(19) United States
(12) Patent Application Publication
(10) Pub. No.: US 2024/0321693 A1
(43) Pub. Date: Sep. 26, 2024

(54) SEMICONDUCTOR DEVICE

(71) Applicant: ROHM CO., LTD., Kyoto-shi (JP)

(72) Inventor: Tomohiro YASUNISHI, Kyoto-shi (JP)

(21) Appl. No.: 18/734,627

(22) Filed: Jun. 5, 2024

Related U.S. Application Data
(63) Continuation of application No. PCT/JP2022/047695, filed on Dec. 23, 2022.

(30) Foreign Application Priority Data
Jan. 20, 2020 (JP) 2022-006874

(51) Int. Cl. H01L 23/49; H01L 23/00; H01L 23/31; H01L 25/07

(52) U.S. Cl. CPC H01L 23/49; H01L 23/3107; H01L 24/40; H01L 25/072; H01L 2224/40137

(57) ABSTRACT

A semiconductor device includes a supporting substrate, a plurality of first semiconductor elements, a plurality of second semiconductor elements, a first terminal, a first conductive member, and a second conductive member. The supporting substrate includes a first conductive part and a second conductive part. The plurality of first semiconductor elements are mounted on the first conductive part and each have a switching function. The plurality of second semiconductor elements are mounted on the second conductive part and each have a switching function. The first terminal protrudes to the first side in the first direction from the first conductive part. The first conductive member electrically connects the plurality of first semiconductor elements and the second conductive part. The second conductive member electrically connects the plurality of second semiconductor elements and the first terminal. The second conductive member is connected to the supporting substrate.

### TECHNICAL FIELD

The present disclosure relates to semiconductor devices.

### BACKGROUND ART

Conventionally, semiconductor devices incorporating power switching elements, such as metal-oxide semiconductor field-effect transistors (MOSFETs) and insulated gate bipolar transistors (IGBTs), have been known. Such semiconductor devices are used in various electronic devices, ranging from industrial devices to home appliances and information terminals, or even to vehicle-mount devices. JP-A-2021-190505 discloses a conventional semiconductor device (power module). The semiconductor device disclosed in JP-A-2021-190505 includes a semiconductor element and a supporting substrate. The semiconductor element is an IGBT made of silicon (Si), for example. The supporting substrate supports the semiconductor element. The supporting substrate includes an insulating base and conductor layers stacked on the opposite sides of the base. The base is made of ceramic, for example. The conductive layers are made of, for example, copper (Cu), and one of the conductive layers is bonded to the semiconductor element. The semiconductor element is covered with the sealing resin.

### BRIEF DESCRIPTION OF THE DRAWINGS

FIG. 1 is a perspective view of a semiconductor device according to a first embodiment of the present disclosure.

FIG. 2 is a perspective view of a fragment of the semiconductor device according to the first embodiment of the present disclosure.

FIG. 3 is a perspective view of a fragment of the semiconductor device according to the first embodiment of the present disclosure.

FIG. 4 is a plan view of the semiconductor device according to the first embodiment of the present disclosure.

FIG. 5 is a plan view of a fragment of the semiconductor device according to the first embodiment of the present disclosure.

FIG. 6 is a side view of a fragment of the semiconductor device according to the first embodiment of the present disclosure.

FIG. 7 is an enlarged plan view of a fragment of the semiconductor device according to the first embodiment of the present disclosure.

FIG. 8 is a plan view of a fragment of the semiconductor device according to the first embodiment of the present disclosure.

FIG. 9 is a plan view of a fragment of the semiconductor device according to the first embodiment of the present disclosure.

FIG. 10 is a side view of the semiconductor device according to the first embodiment of the present disclosure.

FIG. 11 is a bottom view of the semiconductor device according to the first embodiment of the present disclosure.

FIG. 12 is a sectional view taken along line XII-XII of FIG. 5.

FIG. 13 is a sectional view taken along line XIII-XIII of FIG. 5.

FIG. 14 is an enlarged sectional view of a fragment of the semiconductor device according to the first embodiment of the present disclosure.

FIG. 15 is an enlarged sectional view of a fragment of the semiconductor device according to the first embodiment of the present disclosure.

FIG. 16 is a sectional view taken along line XVI-XVI of FIG. 5.

FIG. 17 is a sectional view taken along line XVII-XVII of FIG. 5.

FIG. 18 is a sectional view taken along line XVIII-XVIII of FIG. 5.

FIG. 19 is a sectional view taken along line XIX-XIX of FIG. 5.

FIG. 20 is a sectional view taken along line XX-XX of FIG. 5.

FIG. 21 is an enlarged sectional view of a fragment of the semiconductor device according to the first embodiment of the present disclosure.

FIG. 22 is a perspective view of a second conductive member of the semiconductor device according to the first embodiment of the present disclosure.

FIG. 23 is a perspective view of the second conductive member of the semiconductor device according to the first embodiment of the present disclosure.

FIG. 24 is a plan view of the second conductive member of the semiconductor device according to the first embodiment of the present disclosure.

FIG. 25 is a front view of the second conductive member of the semiconductor device according to the first embodiment of the present disclosure.

FIG. 26 is a bottom view of the second conductive member of the semiconductor device according to the first embodiment of the present disclosure.

FIG. 27 is a side view of the second conductive member of the semiconductor device according to the first embodiment of the present disclosure.

FIG. 28 is an enlarged sectional view of a fragment of a semiconductor device according to a first variation of the first embodiment of the present disclosure.

FIG. 29 is an enlarged sectional view of a fragment of a semiconductor device according to a second variation of the first embodiment of the present disclosure.

FIG. 30 is an enlarged sectional view of a fragment of a semiconductor device according to a third variation of the first embodiment of the present disclosure.

FIG. 31 is an enlarged sectional view of a fragment of a semiconductor device according to a second embodiment of the present disclosure.

FIG. 32 is an enlarged sectional view of a fragment of a semiconductor device according to a first variation of the second embodiment of the present disclosure.

FIG. 33 is an enlarged sectional view of a fragment of a semiconductor device according to a third embodiment of the present disclosure.

FIG. 34 is an enlarged sectional view of a fragment of a semiconductor device according to a first variation of the third embodiment of the present disclosure.

FIG. 35 is an enlarged sectional view of a fragment of a semiconductor device according to a second variation of the third embodiment of the present disclosure.

FIG. 36 is an enlarged sectional view of a fragment of a semiconductor device according to a fourth embodiment of the present disclosure.

### DETAILED DESCRIPTION OF EMBODIMENTS

The following specifically describes preferred embodiments of the present disclosure with reference to the drawings.

In the present disclosure, the terms such as “first”, “second”, “third”, and so on are used merely as labels to identify the items referred to by the terms and are not intended to impose a specific order or sequence on these items.

In the description of the present disclosure, the expression “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expression “An object A is arranged in an object B”, and “An object A is arranged on an object B” imply the situation where, unless otherwise specifically noted, “the object A is arranged directly in or on the object B”, and “the object A is arranged in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a portion of the object B”. Still further, the expression “An object A is connected to an object B” implies the situation where the object A and the object B are fixed to each other in direct contact, and where the object A and the object B are fixed to each other with one or more other components interposed between them.

### First Embodiment

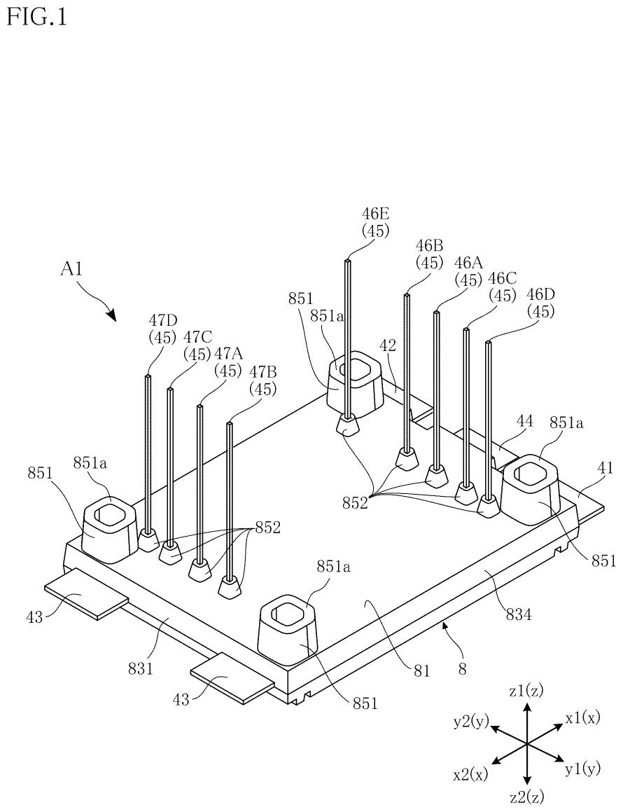

FIGS. 1 to 27 show a semiconductor device according to a first embodiment of the present disclosure. The semiconductor device A1 of the present embodiment includes a plurality of first semiconductor elements 10A, a plurality of second semiconductor elements 10B, a supporting substrate 3, a first terminal 41, a second terminal 42, a plurality of third terminals 43, a fourth terminal 44, a plurality of control terminals 45, a control terminal support 48, a first conductive member 5, a second conductive member 6, and a sealing resin 8.

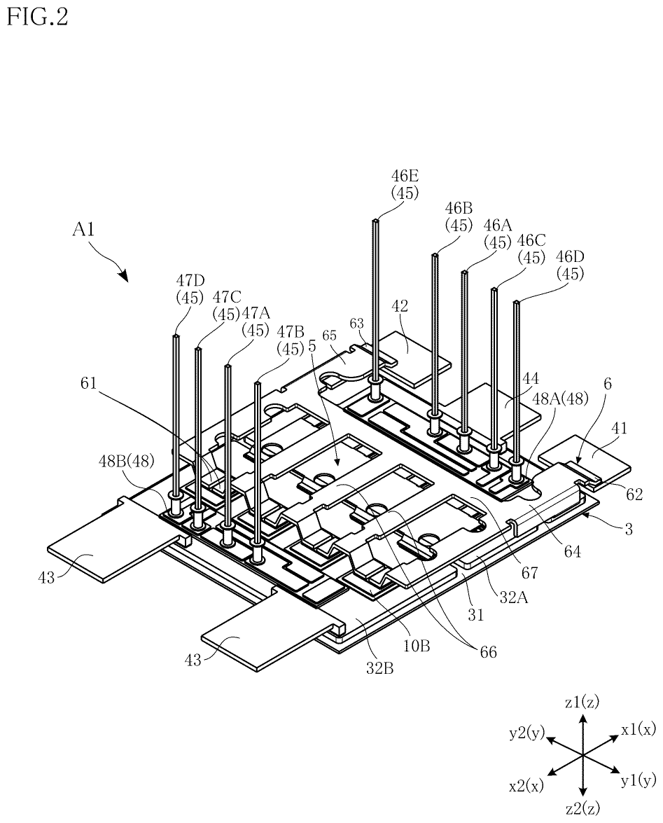

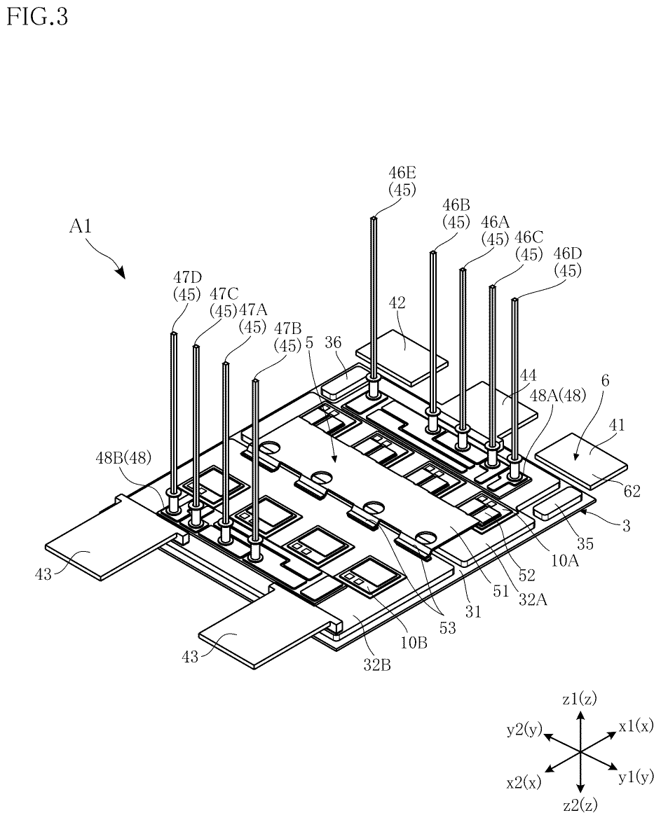

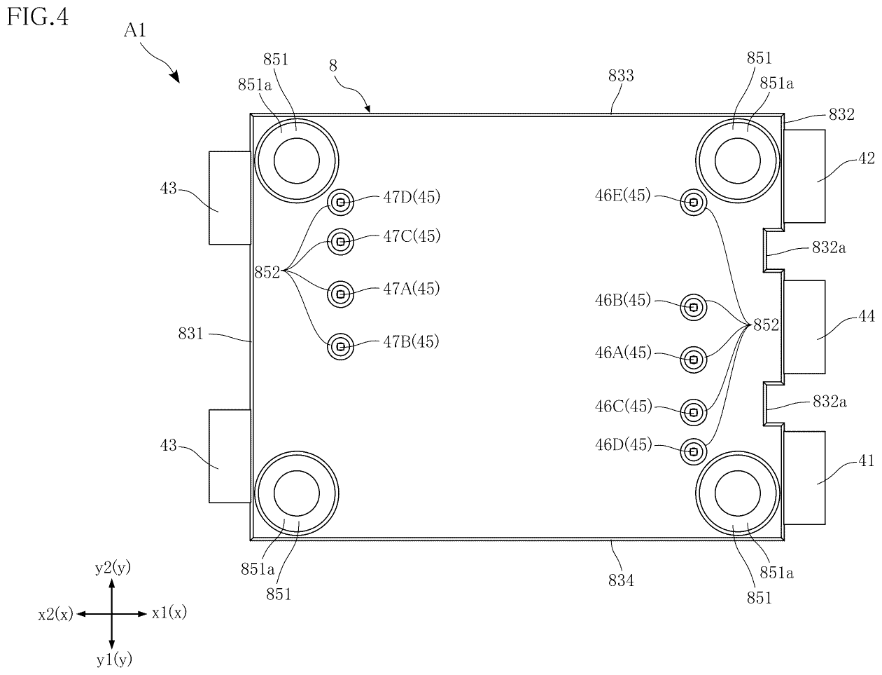

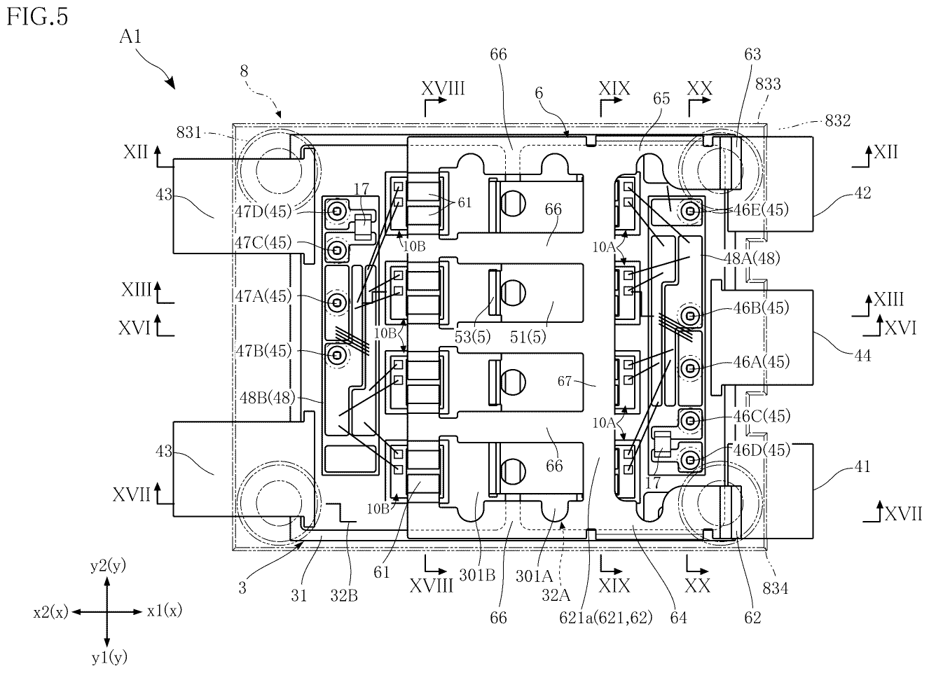

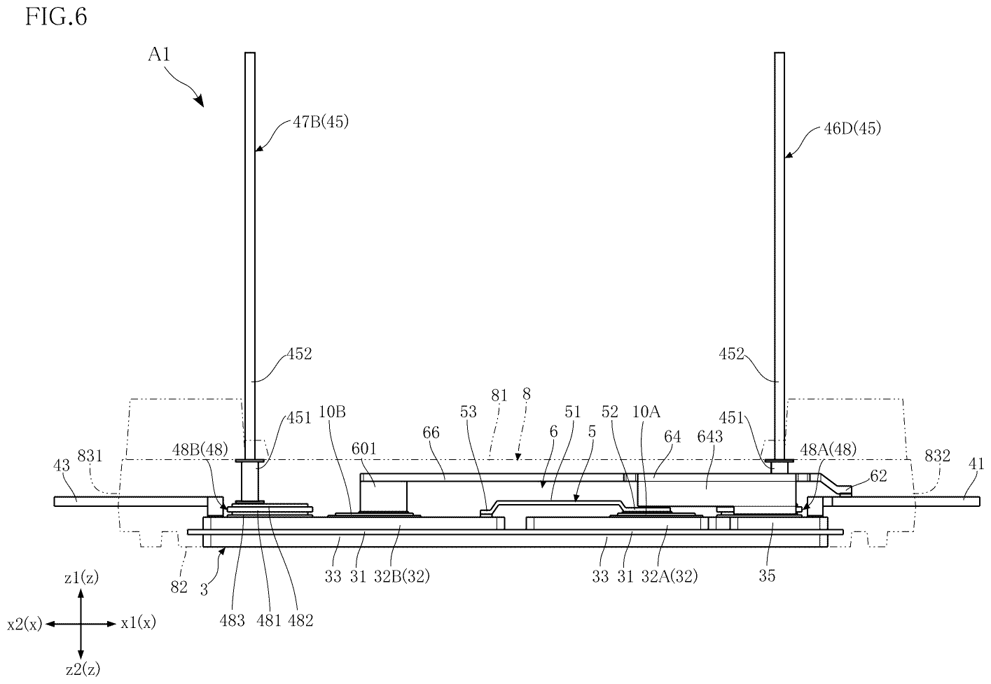

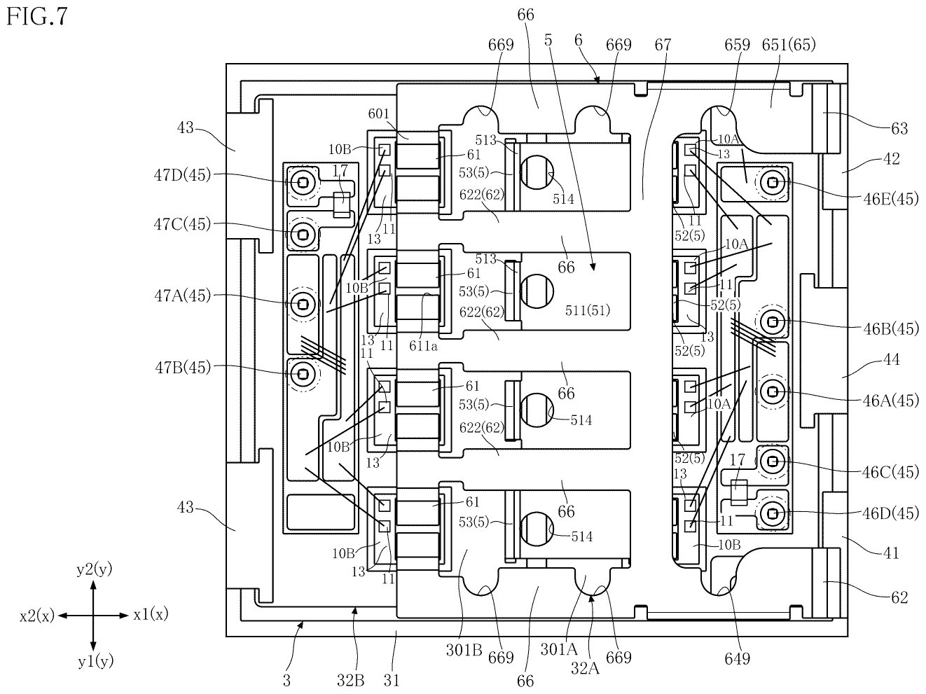

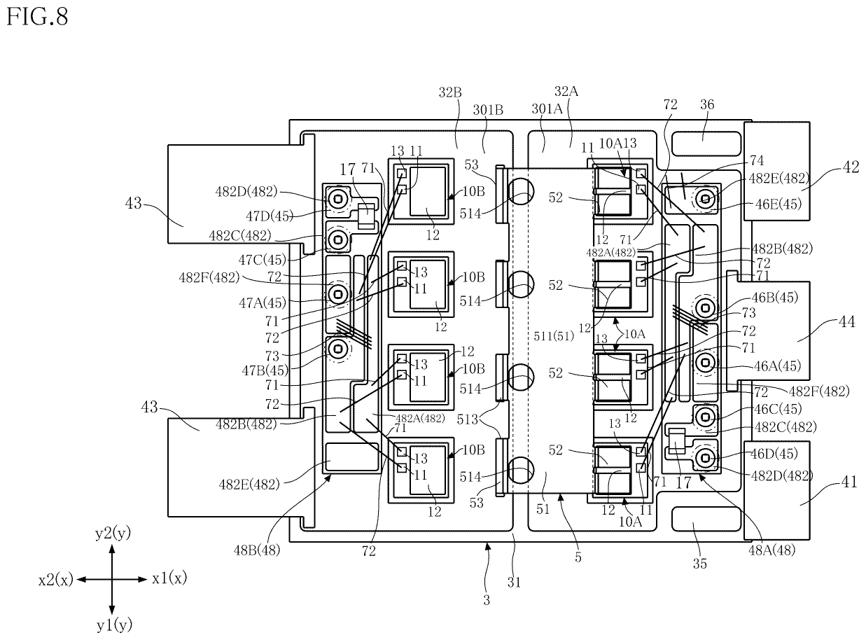

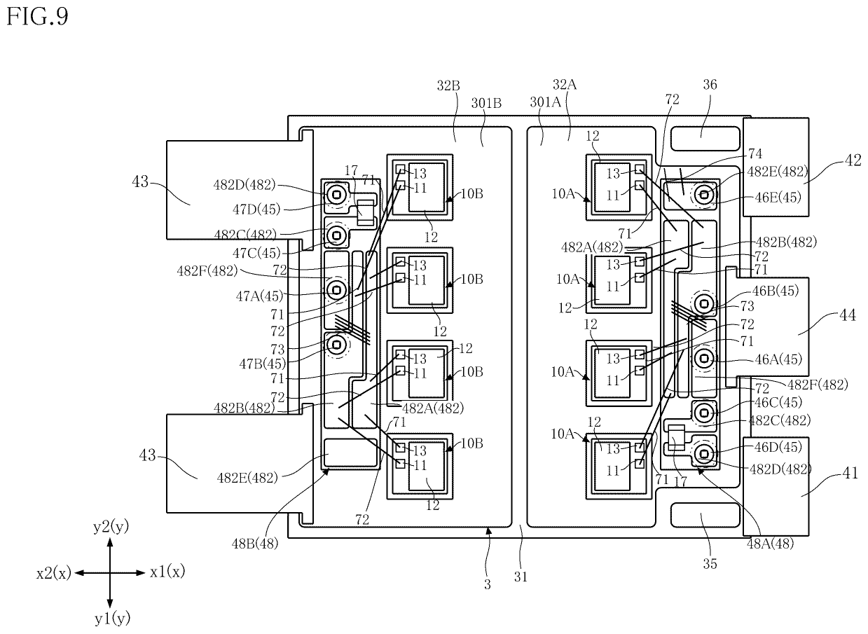

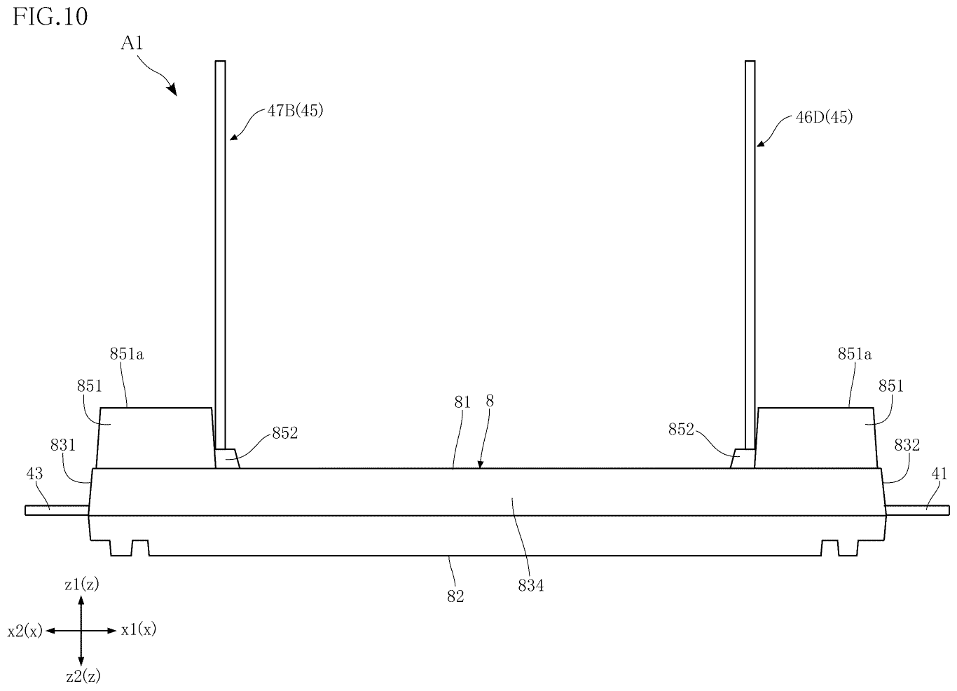

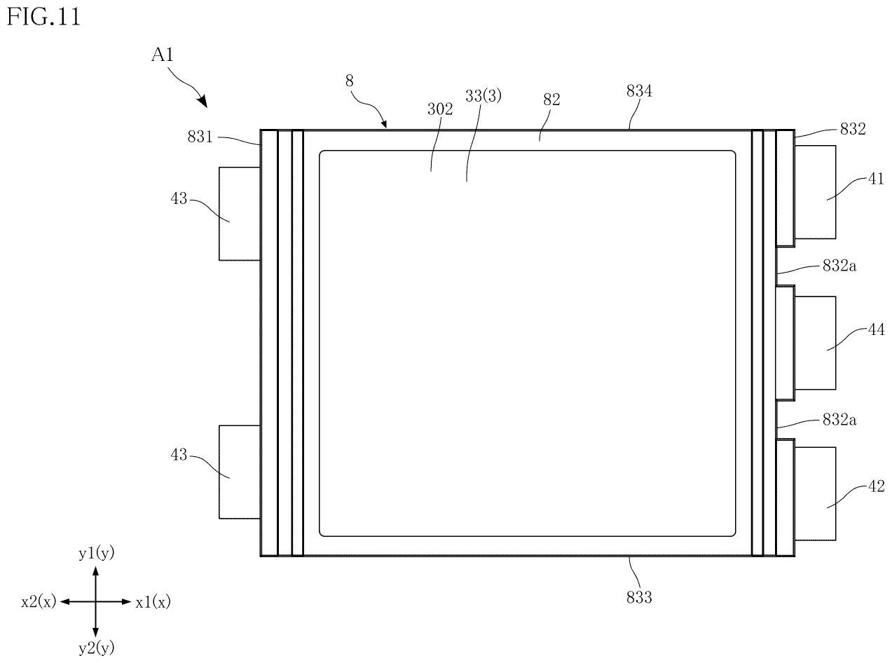

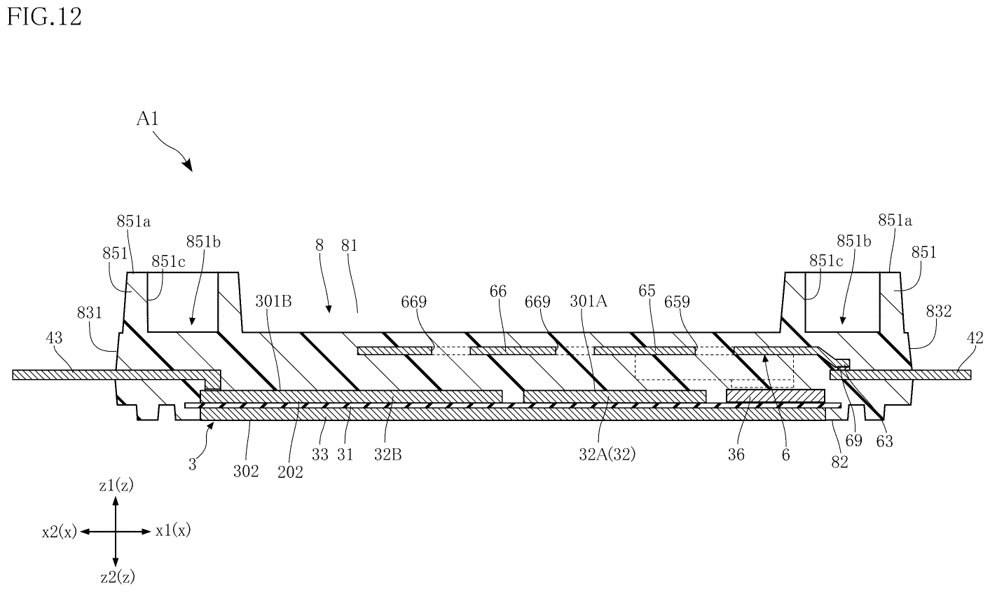

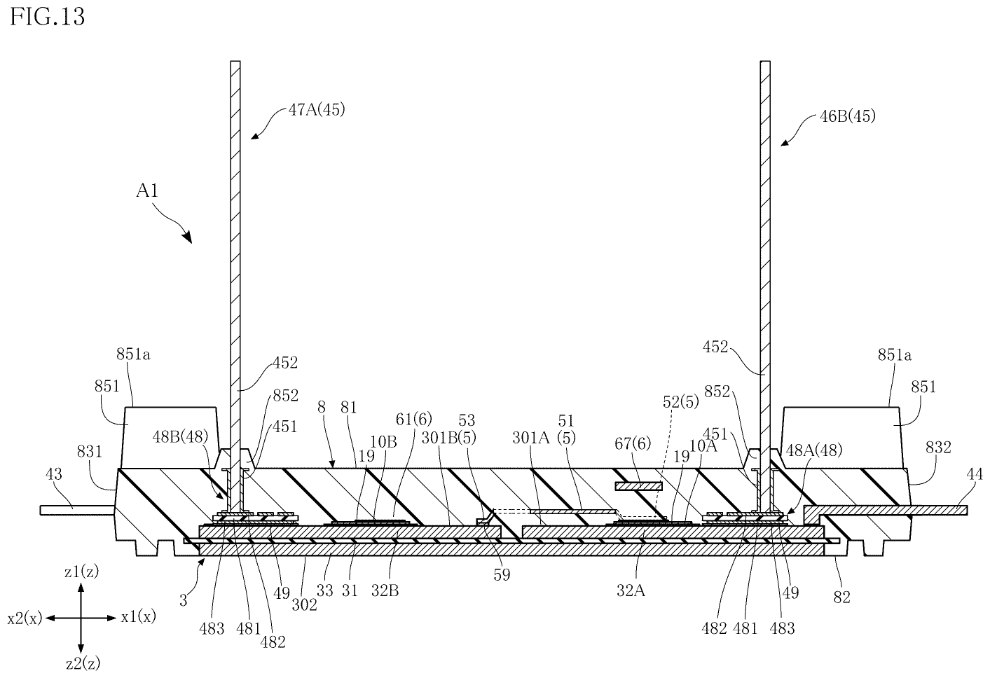

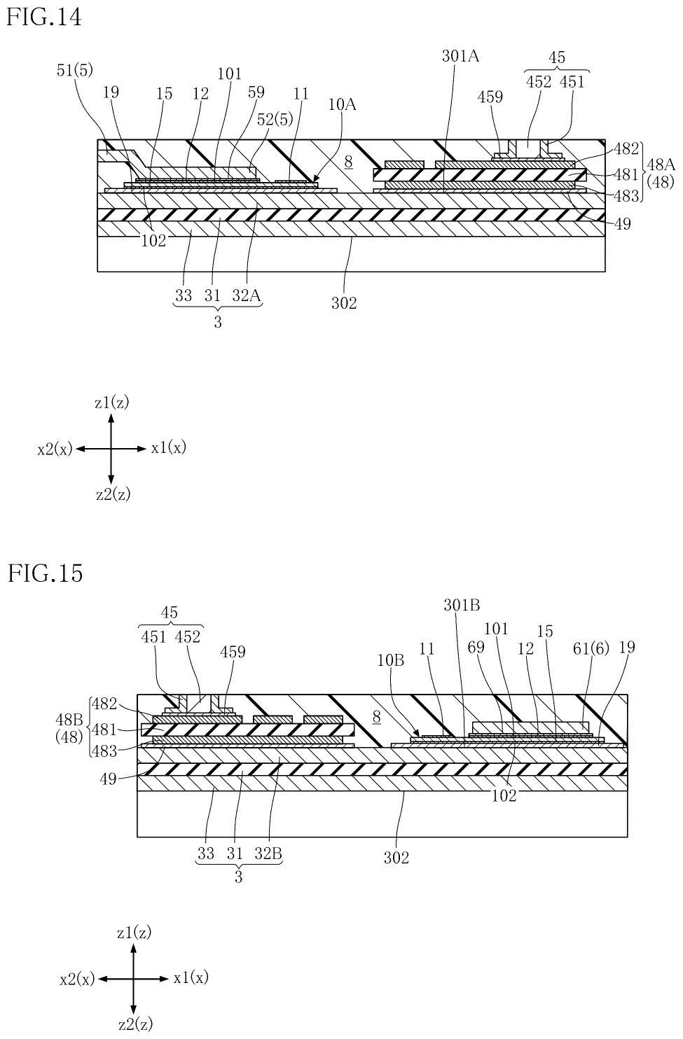

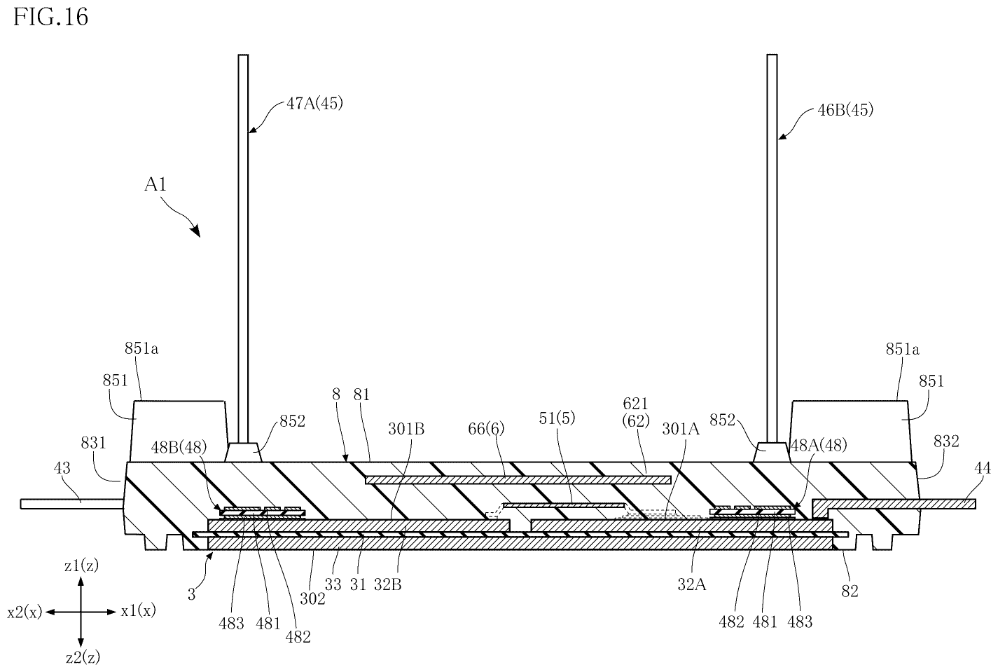

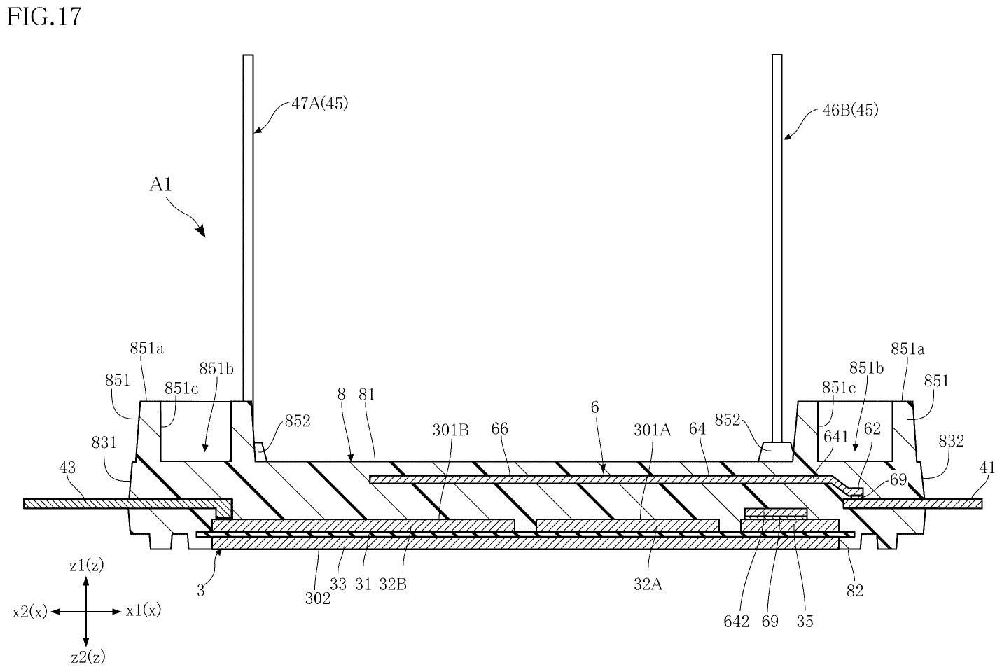

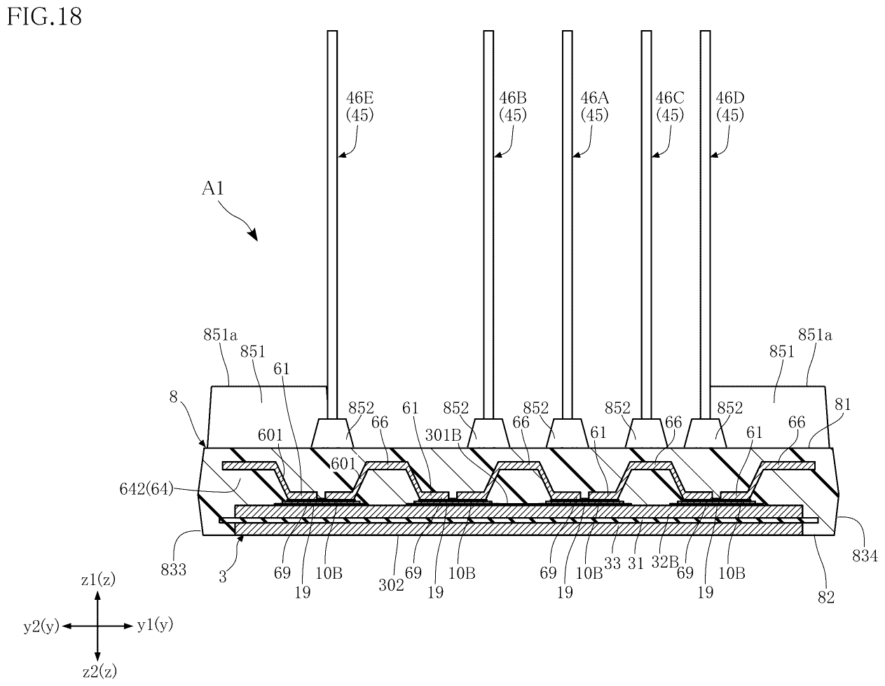

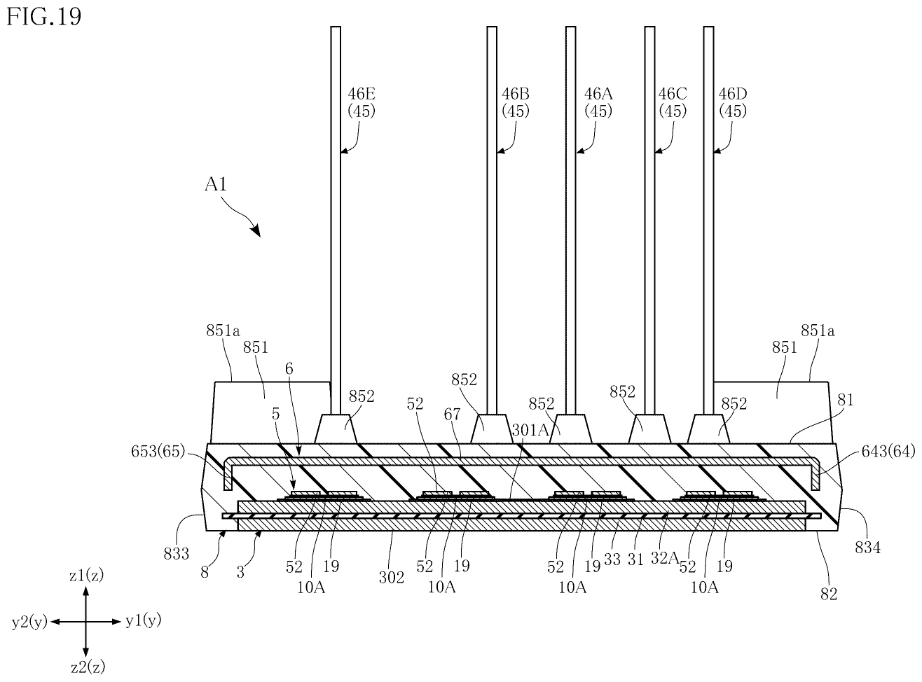

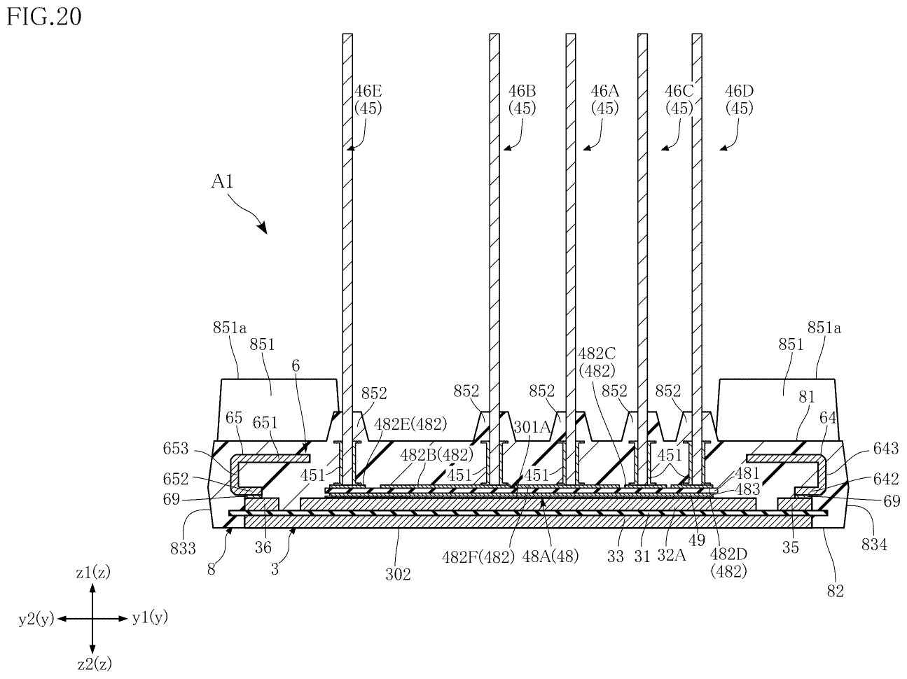

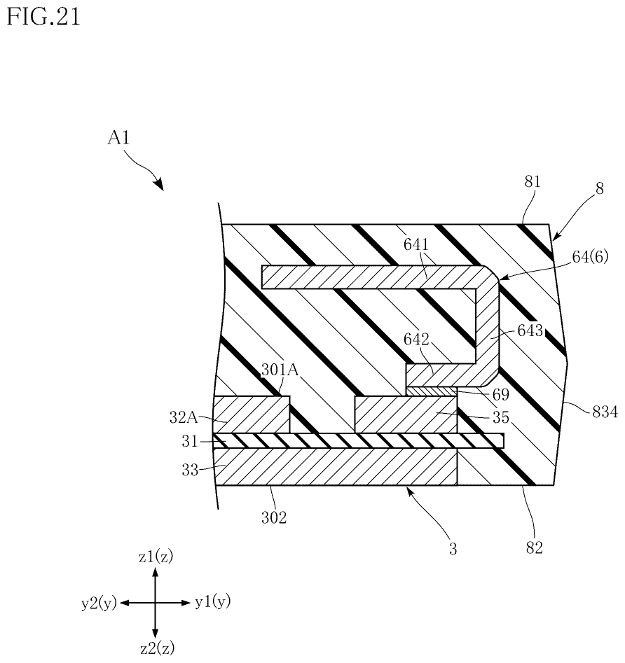

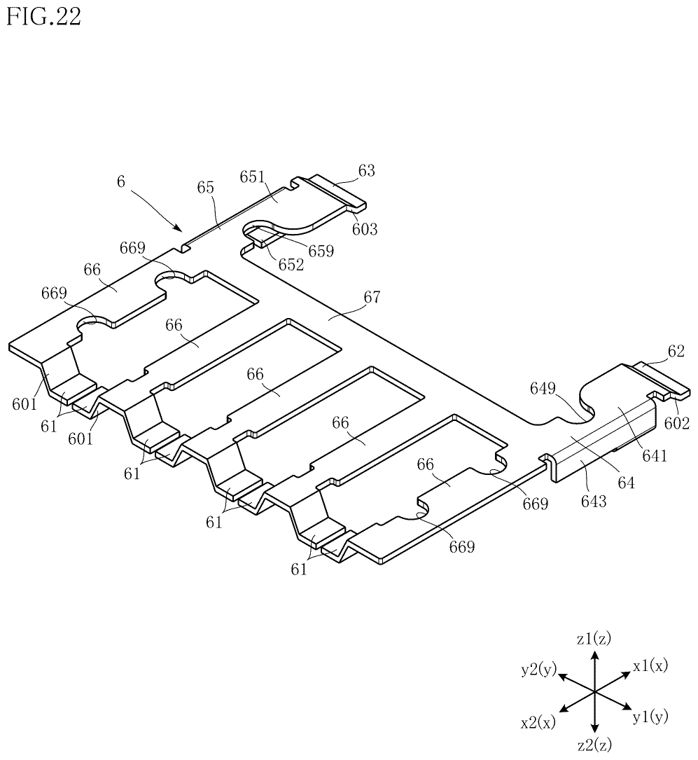

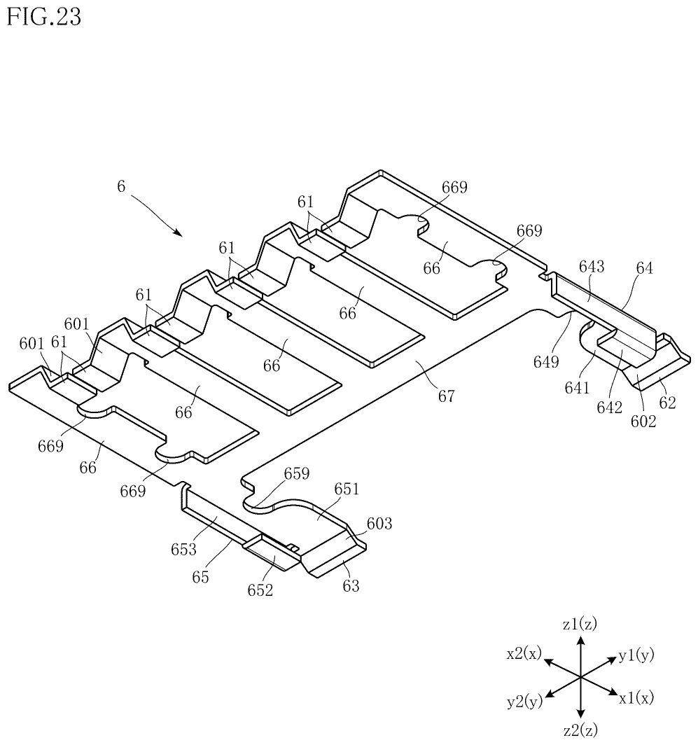

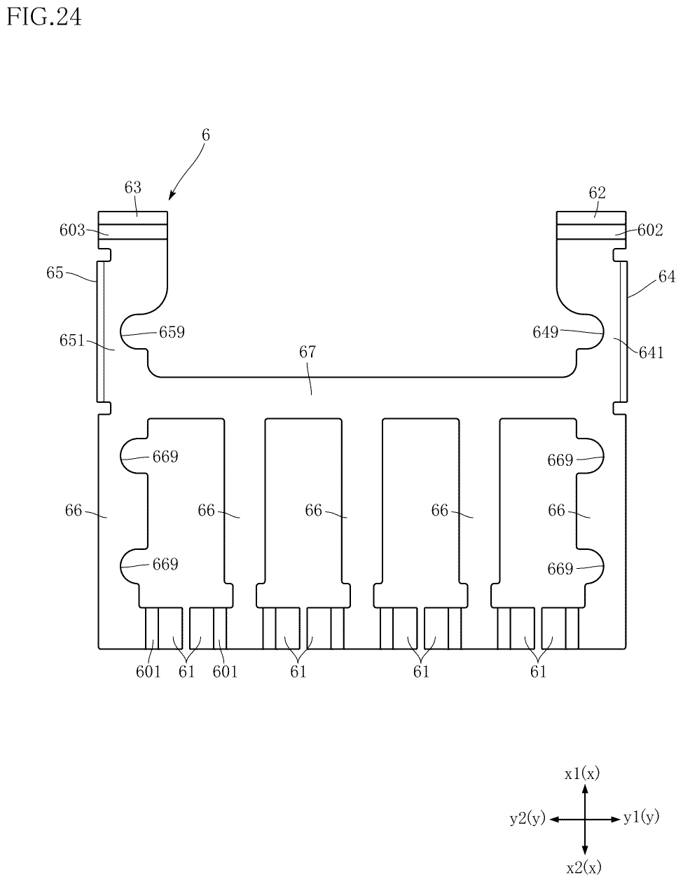

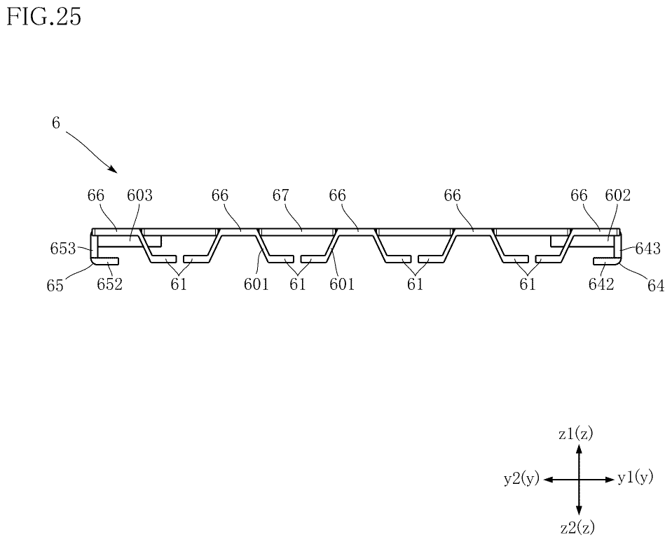

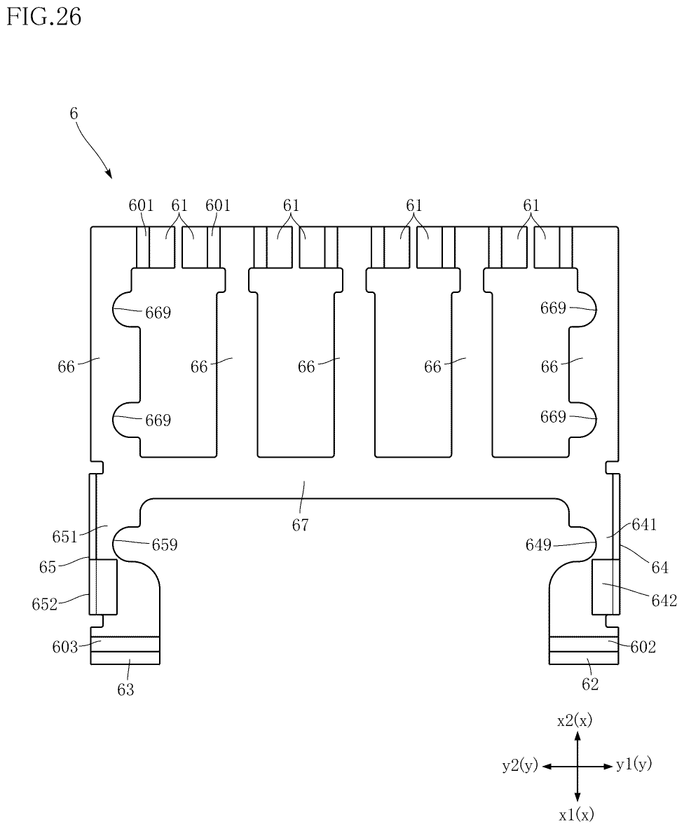

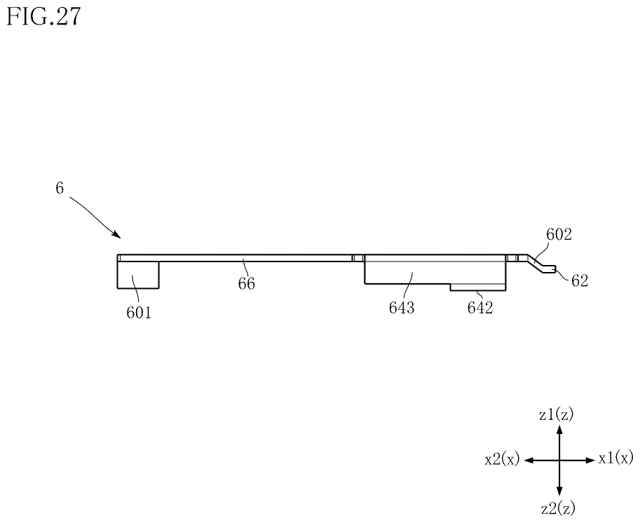

FIG. 1 is a perspective view of the semiconductor device A1. FIGS. 2 and 3 are perspective views of portions of the semiconductor device A1. FIG. 4 is a plan view of the semiconductor device A1. FIG. 5 is a plan view of a fragment of the semiconductor device A1. FIG. 6 is a side view of a fragment of the semiconductor device A1. FIG. 7 is an enlarged plan view of a fragment of the semiconductor device A1. FIGS. 8 and 9 are plan views of portions of the semiconductor device A1. FIG. 10 is a side view of the semiconductor device A1. FIG. 11 is a bottom view of the semiconductor device A1. FIG. 12 is a sectional view taken along line XII-XII of FIG. 5. FIG. 13 is a sectional view taken along line XIII-XIII of FIG. 5. FIGS. 14 and 15 are enlarged sectional views of portions of the semiconductor device A1. FIG. 16 is a sectional view taken along line XVI-XVI of FIG. 5. FIG. 17 is a sectional view taken along line XVII-XVII of FIG. 5. FIG. 18 is a sectional view taken along line XVIII-XVIII of FIG. 5. FIG. 19 is a sectional view taken along line XIX-XIX of FIG. 5. FIG. 20 is a sectional view taken along line XX-XX of FIG. 5. FIG. 21 is an enlarged sectional view of a fragment of the semiconductor device A1. FIG. 22 is a perspective view of the second conductive member 6 of the semiconductor device A1. FIG. 23 is a perspective view of the second conductive member 6 of the semiconductor device A1. FIG. 24 is a plan view of the second conductive member 6 of the semiconductor device A1. FIG. 25 is a front view of the second conductive member 6 of the semiconductor device A1. FIG. 26 is a bottom view of the second conductive member 6 of the semiconductor device A1. FIG. 27 is a side view of the second conductive member 6 of the semiconductor device A1.

For the convenience of description, three mutually orthogonal directions are defined as x, y, and z directions. In one example, the z direction corresponds the thickness direction of the semiconductor device A1. The x direction corresponds the horizontal direction of the semiconductor device A1 in plan view (see FIG. 4). The y direction corresponds to the vertical direction of the semiconductor device A1 in plan view (see FIG. 4). In the following description, “in plan view” refers to the view as seen in the z direction. The x direction is an example of the “first direction”, and the y direction is an example of the “second direction”.

The first semiconductor elements 10A and the second semiconductor elements 10B are electronic components integral to the functionality of the semiconductor device A1. The first semiconductor elements 10A and the second semiconductor elements 10B are each made of a semiconductor material primarily composed of silicon carbide (Sic), for example. The semiconductor material is limited to SiC, and other examples include silicon (Si), gallium nitride (GaN), and diamond (C). For example, the first semiconductor elements 10A and the second semiconductor elements 10B are power semiconductor chips, such as metal-oxide semiconductor field-effect transistors (MOSFETs) each having a switching function. While the first semiconductor elements 10A and the second semiconductor elements 10B are MOSFETs in the present embodiment, this is a non-limiting example. The first semiconductor elements 10A and the second semiconductor elements 10B may be other types of transistors, such as insulated gate bipolar transistors (IGBTs). The first semiconductor elements 10A and the second semiconductor elements 10B are identical elements. The first semiconductor elements 10A and the second semiconductor elements 10B may be n-channel MOSFETs or p-channel MOSFETs.

As shown in FIGS. 14 and 15, each of the first semiconductor elements 10A and the second semiconductor elements 10B has an element obverse surface 101 and an element reverse surface 102. For each of the first semiconductor elements 10A and the second semiconductor elements 10B, the element obverse surface 101 and the element reverse surface 102 are spaced apart in the z direction. The element obverse surface 101 faces in the z1 direction, and the element reverse surface 102 faces in the z2 direction.

In the present embodiment, the semiconductor device A1 includes four first semiconductor elements 10A and four second semiconductor elements 10B. However, the numbers of the respective elements are not limited to four, and can be appropriately adjusted depending on the performance required for the semiconductor device A1. FIGS. 8 and 9 shows an example in which four first semiconductor elements 10A and four second semiconductor 10B element are arranged. Alternatively, however, the numbers of the first semiconductor elements 10A and the second semiconductor elements 10B may be two or three, or even five or more. In addition, the number of the first semiconductor elements 10A and the number of the second semiconductor element 10B may be the same or different. The numbers of the first semiconductor elements 10A and the second semiconductor elements 10B may be determined depending on the current capacity to be handled by the semiconductor device A1.

The semiconductor device A1 is configured as a half-bridge switching circuit, for example. In this case, the first semiconductor elements 10A form an upper arm circuit of the semiconductor device A1, and the second semiconductor elements 10B form a lower arm circuit. In the upper arm circuit, the first semiconductor elements 10A are connected lower arm circuit, the second in parallel. In the semiconductor elements 10B are connected in parallel. In addition, each first semiconductor element 10A and a relevant second semiconductor element 10B are serially connected to form a bridge layer.

As shown in FIGS. 8, 9, and 19 in particular, the first semiconductor elements 10A are mounted on a later-described first conductive part 32A of the supporting substrate 3. In the example shown in FIGS. 8 and 9, the first semiconductor elements 10A are aligned in the y direction at spaced intervals. The first semiconductor element 10A are electrically bonded to the first conductive part 32A via a conductive bonding material 19. The first semiconductor elements 10A are bonded to the first conductive part 32A, with their element reverse surfaces 102 facing the first conductive part 32A. Different from the present embodiment, the first semiconductor elements 10A may be attached to a metal member that is not a part of the substrate, such as a DBC substrate. Such a metal member in this case is an example of the “first conductive part”. The metal member may be supported on the first conductive part 32A.

As shown in FIGS. 8, 9, and 18 in particular, the second semiconductor elements 10B may be attached a later-described second conductive part 32B of the supporting substrate 3. In the example shown in FIGS. 8 and 9, the second semiconductor aligned in the y direction spaced elements 10B are intervals. The second semiconductor elements 10B are electrically bonded to the second conductive part 32B via the conductive bonding material 19. The second semiconductor elements 10B are bonded to the second conductive part 32B, with their element reverse surfaces 102 facing the second conductive part 32B. As can be understood from FIG. 9, the first semiconductor elements 10A and the second semiconductor elements 10B overlap with each other as viewed in the x direction. However, the first semiconductor elements 10A and the second semiconductor elements 10B may be arranged without such an overlap. Different from the present embodiment, the second semiconductor elements 10B may be attached to a metal member that is not a part of the substrate, such as a DBC substrate. The metal member in this case is an example of the “second conductive part”. The metal member may be supported on the second conductive part 32B.

Each of the first semiconductor elements 10A and the second semiconductor elements 10B includes a first obverse-surface electrode 11, a second obverse-surface electrode 12, a third obverse-surface electrode 13, and a reverse-surface electrode 15. The description given below of the first obverse-surface electrode 11, the second obverse-surface electrode 12, the third obverse-surface electrode 13, and the reverse-surface electrode 15 is common to all of the first semiconductor elements 10A and the second semiconductor elements 10B. The first obverse-surface electrode 11, the second obverse-surface electrode 12, and the third obverse-surface electrode 13 are disposed on the element obverse surface 101. The first obverse-surface electrode 11, the second obverse-surface electrode 12, and the third obverse-surface electrode 13 are insulated by an insulating film not shown in the figures. The reverse-surface electrode 15 is disposed on the element reverse surface 102.

The first obverse-surface electrode 11 is the gate electrode, for example, and receives a drive signal (e.g., gate voltage) inputted to drive the first semiconductor element 10A (the second semiconductor element 10B). The second obverse-surface electrode 12 is the source electrode, for example, and conducts the source current of the first semiconductor element 10A (the second semiconductor element 10B). The third obverse-surface electrode 13 is a source-sense electrode, for example, and carries the source current. The reverse-surface electrode 15 is the drain electrode, for example, and conducts the drain current. The reverse-surface electrode 15 covers the entire region (or substantially the entire region) of the element reverse surface 102. The reverse-surface electrode 15 may be a silver (Ag) plating, for example.

The first semiconductor elements 10A (the second semiconductor elements 10B) each switch between a conducting state and a non-conducting state in response to a drive signal (gate voltage) inputted to the first obverse-surface electrode 11 (the gate electrode). The conducting state allows a current to flow from the reverse-surface electrode 15 (the drain electrode) to the second obverse-surface electrode 12 (the source electrode), but the non-conducting state does not allow this current flow. In short, the first semiconductor elements 10A (the second semiconductor elements 10B) each perform a switching operation. The semiconductor device A1 converts the DC voltage applied between the fourth terminal 44 and each of the first terminal 41 and the second terminal 42 into, for example, AC voltage by switching the first semiconductor elements 10A and the second semiconductor elements 10B, and outputs the resulting AC voltage from the third terminals 43.

The semiconductor device A1 includes a thermistor 17 as shown in FIGS. 5, 8, and 9 in particular. The thermistor 17 is used as a temperature sensor. The semiconductor device A1 may include a temperature-sensing diode in addition to, or alternatively to the thermistor 17.

The supporting substrate 3 supports the first semiconductor elements 10A and second semiconductor elements 10B. The specific configuration of the supporting substrate 3 is not limited, and the supporting substrate 3 may be composed of a direct bonded copper (DBC) substrate or an active metal brazing (AMB) substrate. The supporting substrate 3 includes an insulating layer 31, the first conductive part 32A, the second conductive part 32B, and a reverse-surface metal layer 33. The supporting substrate 3 of the present embodiment additionally includes a first metal part 35 and a second metal part 36. The supporting substrate 3 has a z-direction dimension of at least 0.4 mm and at most 3.0 mm, for example.

The insulating layer 31 is made of a ceramic material with excellent thermal conductivity. Examples of such a ceramic material include silicon nitride (SiN). The insulating layer 31 is not limited to ceramic and may be an insulating resin sheet, for example. The insulating layer 31 is rectangular in plan view, for example. The insulating layer 31 has a z-direction dimension of at least 0.05 mm and at most 1.0 mm, for example.

The first conductive part 32A supports the first semiconductor elements 10A, and the second conductive part 32B supports the second semiconductor elements 10B. The first conductive part 32A and the second conductive part 32B are formed on the upper surface (the surface facing in the z1 direction) of the insulating layer 31. The first conductive part 32A and the second conductive part 32B are made of a material containing copper (Cu), for example. The material may contain aluminum (Al) instead of Cu. The first conductive part 32A and the second conductive part 32B are spaced apart in the x direction. The first conductive part 32A is located in the x1 direction from the second conductive part 32B. The first conductive part 32A and the second conductive part 32B are each rectangular in plan view, for example. The first conductive part 32A and the second conductive part 32B, together with the first conductive member 5 and the second conductive member 6, form the path of the main circuit current that is switched by the first semiconductor elements 10A and the second semiconductor elements 10B.

The first conductive part 32A has a first obverse surface 301A. The first obverse surface 301A is a flat plane facing in the z1 direction. The first semiconductor elements 10A are bonded to the first obverse surface 301A of the first conductive part 32A via the conductive bonding material 19. The second conductive part 32B has a second obverse surface 301B. The second obverse surface 301B is a flat plane facing in the z1 direction. The second semiconductor elements 10B are bonded to the second obverse surface 301B of the second conductive part 32B via the conductive bonding material 19. The conductive bonding material 19 may be, but not limited to, solder, metal paste, or sintered metal, for example. The first conductive part 32A and the second conductive part 32B each have a z-direction dimension of at least 0.1 mm and at most 1.5 mm, for example.

Similarly to the first conductive part 32A and the second conductive part 32B, the first metal part 35 is formed on the insulating layer 31. The first metal part 35 is spaced apart from the first conductive part 32A and the second conductive part 32B and is insulated from the first conductive part 32A and the second conductive part 32B.

The first metal part 35 is made of metal. The material of the first metal part 35 may be the same material as that of the first conductive part 32A and the second conductive part 32B, for example. The z-direction dimension of the first metal part 35 is not limited and may be as large as those of the first conductive part 32A and the second conductive part 32B. The arrangement of the first metal part 35 is not limited. In the present embodiment, the first metal part 35 is located near the edges of the insulating layer 31 in the x1 direction and the y1 direction, as shown FIG. 9. In the illustrated example, the first conductive part 32A has a recess as viewed in the z direction, such that the first metal part 35 is accommodated within the recess. The shape of the first metal part 35 is not limited. In the illustrated example, the first metal part 35 has a rectangular shape that is elongated in the x direction.

The second metal part 36 is made of metal. The material of the second metal part 36 may be the same material as that of the first conductive part 32A and the second conductive part 32B, for example. The z-direction dimension of the second metal part 36 is not limited and may be as large as those of the first conductive part 32A and the second conductive part 32B. The arrangement of the second metal part 36 is not limited. In the present embodiment, the second metal part 36 is located near the edges of the insulating layer 31 in the x1 direction and the y2 direction, as shown FIG. 9. In the illustrated example, the first conductive part 32A has a recess as viewed in the z direction, such that the second metal part 36 is accommodated within the recess. The shape of the second metal part 36 is not limited. In the illustrated example, the second metal part 36 has a rectangular shape that is elongated in the x direction. In the illustrated example, the first metal part 35 and the second metal part 36 are spaced apart in the y direction across a portion of the first conductive part 32A.

The reverse-surface metal layer 33 is disposed on the lower surface (the surface facing in the z2 direction) of the insulating layer 31. The reverse-surface metal layer 33 is made of the same material as that of a first metal layer 32. The reverse-surface metal layer 33 has a reverse surface 302. The reverse surface 302 is a flat plane facing in the z2 direction. In the example shown in FIG. 11, the reverse surface 302 is exposed from, for example, the sealing resin 8. The reverse surface 302 is available for attachment of, for example, a heat dissipating member (such as a heat sink) not illustrated in the figure. The reverse surface 302 may be covered with the sealing resin 8, instead of being exposed from the sealing resin 8. In plan view, the reverse-surface metal layer 33 overlaps with both the first conductive part 32A and the second conductive part 32B. The reverse-surface metal layer 33 also overlaps with both the first metal part 35 and the second metal part 36 in plan view.

The first terminal 41, the second terminal 42, the third terminals 43, and the fourth terminal 44 are made with metal plates. The material of the metal plates may be copper (Cu) or a Cu alloy, for example. In the example shown in FIGS. 1 to 5, 8, 9, and 11, the semiconductor device A1 includes one first terminal 41, one second terminal 42, one fourth terminal 44, and two third terminals 43, but the numbers of the respective terminals are not limited to these.

The first terminal 41, the second terminal 42, and the fourth terminal 44 are input terminals for DC voltage that is to be converted. The fourth terminal 44 is a positive electrode (P terminal), and the first terminal 41 and the second terminal 42 are negative electrodes (N terminals). The third terminals 43 are output terminals for the AC voltage converted by the first semiconductor elements 10A and the second semiconductor elements 10B. The first terminal 41, the second terminal 42, the third terminals 43, and the fourth terminal 44 each have a portion covered with the sealing resin 8 and a portion exposed from the sealing resin 8.

As shown in FIG. 13, the fourth terminal 44 is electrically bonded to the first conductive part 32A. The method for the electrical bonding is not limited and may be selected from options, including ultrasonic bonding, laser bonding, welding, and bonding with the use of solder, metal paste, or a sintered silver, for example. As shown in FIGS. 8 and 9, the fourth terminal 44 is located on the side in the x1 direction from the first semiconductor elements 10A and the first conductive part 32A. The fourth terminal 44 is electrically connected to the first conductive part 32A and also to the reverse-surface electrodes 5 (the drain electrodes) of the first semiconductor elements 10A via the first conductive part 32A.

As shown in FIG. 8, the first terminal 41 and the second terminal 42 are spaced apart from the first conductive part 32A. As shown in FIGS. 5 and 7, the second conductive member 6 is bonded to the first terminal 41 and the second terminal 42. The first terminal 41 and the second terminal 42 may be electrically connected to the second conductive member 6 in any manner. For example, the first terminal 41 and the second terminal 42 may be integrally formed with the second conductive member 6, rather than being joined to have bonded parts. As shown in FIGS. 5 and 8, the first terminal 41 and the second terminal 42 are located on the side in the x1 direction from the first semiconductor elements 10A and the first conductive part 32A. The first terminal 41 and the second terminal 42 are electrically connected to the second conductive member 6 and also to the second obverse-surface electrodes 12 (the source electrodes) of the second semiconductor elements 10B via the second conductive member 6.

As shown in FIGS. 1 to 5 and 11 in particular, for the semiconductor device A1, the first terminal 41, the second terminal 42, and the fourth terminal 44 protrude from the sealing resin 8 in the x1 direction. The first terminal 41, the second terminal 42, and the fourth terminal 44 are spaced apart from each other. The first terminal 41 and the second terminal 42 are located on the opposite sides of the fourth terminal 44 in the y direction. The first terminal 41 is located in the y1 direction from the fourth terminal 44, and the second terminal 42 is located in the y2 direction from the fourth terminal 44. The first terminal 41, the second terminal 42, and the fourth terminal 44 overlap with each other as viewed in the y direction.

As can be understood from FIGS. 8, 9, and 12, each of the two third terminals 43 is electrically bonded to the second conductive part 32B. The method for the electrical bonding is not limited and may be selected from options, including ultrasonic bonding, laser bonding, welding, and bonding with the use of solder, or metal paste, a sintered silver, for example. As shown in FIG. 8 in particular, the two third terminals 43 are located on the side in the x2 direction from the second semiconductor elements 10B and the second conductive part 32B. Each third terminal 43 is electrically connected to the second conductive part 32B and also to the reverse-surface electrodes 15 (the drain electrodes) of the second semiconductor elements 10B via the second conductive part 32B. Note that the number of the third terminals 43 is not limited to two. For example, one third terminal 43 may be provided, or three or more third terminals 43 may be provided. In the case where one third terminal 43 is provided, the one third terminal 43 is preferably connected to the central portion of the second conductive part 32B in the y direction.

The control terminals 45 are pin-like terminals for controlling the first semiconductor elements 10A and the second semiconductor elements 10B. The control terminals 45 include a plurality of first control terminals 46A to 46E and a plurality of second control terminals 47A to 47D. The first control terminals 46A to 46E are used to, for example, control the first semiconductor elements 10A. The second control terminals 47A to 47D are used to, for example, control the second semiconductor elements 10B.

The first control terminals 46A to 46E are arranged at spaced intervals in the y direction. As shown in FIGS. 8, 13, and 20 in particular, the first control terminals 46A to 46E are supported on the first conductive part 32A via the control terminal support 48 (a first support part 48A described later). As shown in FIGS. 5 and 8, in the x direction, the first control terminals 46A to 46E are located between the first semiconductor elements 10A and the first, second, and fourth terminals 41, 42, and 44.

The first control terminal 46A is an input terminal for a drive signal (gate terminal) of the first semiconductor elements 10A. The first control terminal 46A receives a drive signal (e.g., gate voltage) inputted for driving the first semiconductor elements 10A.

The first control terminal 46B is a sensing terminal for a source signal of the first semiconductor elements 10A (a source sense terminal). The first control terminal 46B is used to detect the voltage applied to the second obverse-surface electrodes 12 (the source electrodes) of the first semiconductor elements 10A (the voltage corresponding to the source current).

The first control terminals 46C and 46D are electrically connected to a thermistor 17.

The first control terminal 46E is a sensing terminal for a drain signal of the first semiconductor elements 10A (drain-sense terminal). The first control terminal 46E is used to detect the voltage applied to the reverse-surface electrodes 15 (the drain electrodes) of the first semiconductor elements 10A (the voltage corresponding to the drain current).

The second control terminals 47A to 47D are arranged at spaced intervals in the y direction. As shown in FIGS. 8 and 13 in particular, the second control terminals 47A to 47D are supported on the second conductive part 32B via the control terminal support 48 (a second support part 48B described later). As shown in FIGS. 5 and 8, in the x direction, the second control terminals 47A to 47D are located between the second semiconductor elements 10B and the two third terminals 43.

The second control terminal 47A is an input terminal for a drive signal (gate terminal) of the second semiconductor elements 10B. The second control terminal 47A receives a drive signal (e.g., gate voltage) inputted for driving the second semiconductor elements 10B. The second control terminal 47B is a sensing terminal for a source signal of the second semiconductor elements 10B (a source sense terminal). The second control terminal 47B is used to detect the voltage applied to the second obverse-surface electrodes 12 (the source electrodes) of the second semiconductor elements 10B (the voltage corresponding to the source current). The second control terminals 47C and 47D are electrically connected to a thermistor 17.

Each of the control terminal 45 (the first control terminals 46A to 46E and the second control terminals 47A to 47D) includes a holder 451 and a metal pin 452.

The holder 451 is made of a conductive material. As shown in FIGS. 14 and 15, the holder 451 is bonded to the terminal support 48 (the first metal layer 482 control described later) via a conductive bonding material 459. The holder 451 includes a tubular part, an upper flange, and a lower flange. The upper flange extends from the upper end of the tubular part, and the lower flange extends from the lower end. The metal pin 452 is inserted into the holder 451, extending at least from the upper flange to the tubular part. The holder 451 is covered with the sealing resin 8 (a second projection 852 described later).

The metal pin 452 is a rod-like member extending in the z direction. The metal pin 452 is pressed into the holder 451 and supported by the holder 451. The metal pin 452 is electrically connected to the control terminal support 48 (the first metal layer 482 described later) at least via the holder 451. As in the example shown in FIGS. 14 and 15, the lower end (the end in the z2 direction) of the metal pin 452 may be in contact with the conductive bonding material 459 within the insertion hole of the holder 451. In which case, the metal pin 452 is electrically connected to the control terminal support 48 also via the conductive bonding material 459.

The control terminal support 48 supports the control terminals 45. In the z direction, the control terminal support 48 is located between the first and second obverse surfaces 301A and 301B and the plurality of control terminals 45.

The control terminal support 48 includes a first support part 48A and a second support part 48B. The first support part 48A is disposed on the first conductive part 32A to support the first control terminals 46A to 46E, out of the plurality of control terminals 45. As shown in FIG. 14, the first support part 48A is bonded to the first conductive part 32A via a bonding material 49. The bonding material 49 can either be conductive or insulating, and solder may be used, for example. The second support part 48B is disposed on the second conductive part 32B to support the second control terminals 47A to 47D, out of the plurality of control terminals 45. As shown in FIG. 15, the second support part 48B is bonded to the second conductive part 32B via the bonding material 49.

The control terminal support 48 (each of the first support part 48A and the second support part 48B) may be made with a direct bonded copper (DBC) substrate, for example. The control terminal support 48 includes a stack of an insulating layer 481, a first metal layer 482, and a second metal layer 483.

The insulating layer 481 is made ceramic material, for example. The insulating layer 481 is rectangular in plan view, for example.

As shown in FIGS. 14 and 15 in particular, the first metal layer 482 is formed on the upper surface of the insulating layer 481. Each control terminal 45 stands on the first metal layer 482. The first metal layer 482 is made of Cu or a Cu alloy, for example. As shown in FIG. 8 in particular, the first metal layer 482 includes a first part 482A, a second part 482B, a third part 482C, a fourth part 482D, a fifth part 482E, and a sixth part 482F. The first part 482A, the second part 482B, the third part 482C, the fourth part 482D, the fifth part 482E, and the sixth part 482F are spaced apart from each other and insulated from each other.

A plurality of wires 71 are bonded to the first part 482A to electrically connect the first part 482A to the first obverse-surface electrodes 11 (the gate electrodes) of the first semiconductor elements 10A (the second semiconductor elements 10B). A plurality of wires 73 are connected to each of the first part 482A and the sixth part 482F. This electrically connects the sixth part 482F to the first obverse-surface electrodes 11 (the gate electrodes) of the first semiconductor elements 10A (the second semiconductor elements 10B) via the wires 73 and 71. As shown in FIG. 8, the first control terminal 46A is bonded to the sixth part 482F of the first support part 48A, and the second control terminal 47A is bonded to the sixth part 482F of the second support part 48B.

A plurality of wires 72 are bonded to the second part 482B to electrically connect the second part 482B to the second obverse-surface electrodes 12 (the source electrodes) of the first elements (the semiconductor 10A second semiconductor elements 10B). As shown in FIG. 8, the first control terminal 46B is bonded to the second part 482B of the first support part 48A, and the second control terminal 47B is bonded to the second part 482B of the second support part 48B.

A thermistor 17 is bonded to the third part 482C and the fourth part 482D. As shown in FIG. 8, the first control terminals 46C and 46D are respectively bonded to the third part 482C and the fourth part 482D of the first support part 48A. In addition, the second control terminals 47C and 47D are respectively bonded to the third part 482C and the fourth part 482D of the second support part 48B.

A wire 74 is bonded to the fifth part 482E of the first support part 48A to electrically connect the first support part 48A to the first conductive part 32A. As shown in FIG. 8, the first control terminal 46E is bonded to the fifth part 482E of the first support part 48A. The fifth part 482E of the second support part 48B is not electrically connected to any part or component. The wires 71 to 74 mentioned above may be bonding wires, for example. The wires 71 to 74 may be made of a material containing gold (Au), Al or Cu, for example.

As shown in FIGS. 14 and 15 in particular, the second metal layer 483 is formed on the lower surface of the insulating layer 481. As shown in FIG. 14, the second metal layer 483 of the first support part 48A is bonded to the first conductive part 32A via the bonding material 49. As shown in FIG. 15, the second metal layer 483 of the second support part 48B is bonded to the second conductive part 32B via the bonding material 49.

The first conductive member 5 and the second conductive member 6, together with the first conductive part 32A and the second conductive part 32B, form the path of the main circuit current that is switched by the first semiconductor elements 10A and the second semiconductor elements 10B. The first conductive member 5 and the second conductive member 6 are spaced apart from the first obverse surface 301A and the second obverse surface 301B in the z1 direction and overlap with the first obverse surface 301A and the second obverse surface 301B in plan view. In the present embodiment, each of the first conductive member 5 and the second conductive member 6 is made with a metal plate. The metal plate is made of Cu or a Cu alloy, for example. Specifically, the first conductive member 5 and the second conductive member 6 are metal plates having been bent as necessary.

The first conductive member 5 is connected to the second obverse-surface electrodes 12 (the source electrodes) of the first semiconductor elements 10A and the second conductive part 32B, thereby electrically connecting the second obverse-surface electrodes 12 of the first semiconductor elements 10A and the second conductive part 32B. The first conductive member 5 forms the path of the main circuit current that is switched by the first semiconductor elements 10A. As shown in FIGS. 7 and 8, the first conductive member 5 includes a main part 51, a plurality of first bonding parts 52, and a plurality of second bonding parts 53.

The main part 51 is located between the first semiconductor elements 10A and the second conductive part 32B in the x direction and has the shape of a strip extending in the y direction in plan view. The main part 51 overlaps with both the first conductive part 32A and the second conductive part 32B in plan view, is spaced apart from the first obverse surface 301A and the second obverse surface 301B in the z1 direction, and is spaced apart from the first obverse surface 301A and the second obverse surface 301B in the z1 direction. As shown in FIG. 16 in particular, the main part 51 is located in the z2 direction from third path parts 66 and a fourth path part 67 of the second conductive member 6 described later, and is closer to the first obverse surface 301A and the second obverse surface 301B than the third path parts 66 and the fourth path part 67.

In the present embodiment, the main part 51 is parallel to the first obverse surface 301A and the second obverse surface 301B, and overlaps with both the first conductive part 32A and the second conductive part 32B in plan view.

As shown in FIG. 8 in particular, the main part 51 extends in the y direction to cover the region where the first semiconductor elements 10A are positioned. As shown in FIGS. 7, 8, and 13 in particular, the main part 51 is formed with a plurality of first openings 514. The first openings 514 may be through-holes extending in the z direction (the direction of the plate thickness of the main part 51). The first openings 514 are aligned at spaced intervals in the y1 direction. The first opening 514 are formed for the respective first semiconductor elements 10A. In the present embodiment, the main part 51 is formed with four first openings 514, each of which corresponds in position in the y direction to one of the plurality of (four) first semiconductor elements 10A.

In plan view, the first openings 514 of the present embodiment overlap with the space between the first conductive part 32A and the second conductive part 32B as shown in FIGS. 8 and 13. When a resin material is injected in the molten state for forming the sealing resin 8, the first openings 514 facilitate the flow of the molten resin material between the upper region (in the z1 direction) and the lower region (in the z2 direction) around the main part 51 (the first conductive member 5).

As shown in FIG. 8 in particular, the first bonding parts 52 and the second bonding parts 53 are connected to the main part 51 via bends and correspond in position to the first semiconductor elements 10A. Specifically, the first bonding parts 52 are located in the x1 direction from the main part The second bonding parts 53 are located in the x2 51. direction from the main part 51. As shown in FIG. 14, each first bonding part 52 is bonded to the second obverse-surface electrode 12 of a corresponding first semiconductor element 10A via a conductive bonding material 59. Each second bonding part 53 is bonded to the second conductive part 32B via the conductive bonding material 59. The conductive bonding material 59 may be, but not limited to, solder, metal paste, or sintered metal, for example.

The second conductive member 6 is connected to the second obverse-surface electrodes 12 (the source electrodes) of the second semiconductor elements 10B, the first terminal 41, and the second terminal 42, thereby electrically connecting the second obverse-surface electrodes 12 of the second semiconductor elements 10B and the first and second terminals 41 and 42. The second conductive member 6 forms the path of the main circuit current that is switched by the second semiconductor elements 10B. As shown in FIGS. 7 and 21 to 27, the second conductive member 6 includes a plurality of third bonding parts 61, a fourth bonding part 62, a fifth bonding part 63, a first path part 64, a second path part 65, a plurality of third path parts 66, and a fourth path part 67.

The third bonding parts 61 are bonded to the second semiconductor elements 10B. Each third bonding part 61 is bonded to the second obverse-surface electrode 12 of a second semiconductor element 10B via a conductive bonding material 69. The conductive bonding material 69 may be, but not limited to, solder, metal paste, or sintered metal, for example. In the present embodiment, two third bonding parts 61 are bonded to the second obverse-surface electrode 12 of each second semiconductor element 10B. The two third bonding parts 61 are spaced apart in the y direction across the central portion of the corresponding second obverse-surface electrode 12.

The fourth bonding part 62 is bonded to the first terminal 41. The fourth bonding part 62 and the first terminal 41 are bonded via the conductive bonding material 69. The conductive bonding material 69 may be, but not limited to, solder, metal paste, or sintered metal, for example.

The fifth bonding part 63 is bonded to the second terminal 42. The fourth bonding part 62 and the second terminal 42 are bonded via the conductive bonding material 69. The conductive bonding material 69 may be, but not limited to, solder, metal paste, or sintered metal, for example.

The first path part 64 is located between the third bonding parts 61 and the fourth bonding part 62. In the illustrated example, the first path part 64 has a bend connected to the fourth bonding part 62. In in plan view, the first path part 64 overlaps with the first conductive part 32A and the first metal part 35. The first path part 64 generally extends in the x direction.

The first path part 64 includes a first band-shaped portion 641, a first connecting portion 642, and a first coupling portion 643. The first band-shaped portion 641 is located in the z1 direction from the fourth bonding part 62 and is substantially parallel to the first obverse surface 301A. The first band-shaped portion 641 generally extends in the x direction. In the illustrated example, the first band-shaped portion 641 has a recess 649. The recess 649 is a portion of the first band-shaped portion 641 that is recessed in the y1 direction. In FIG. 5, the first metal part 35 is visible through the recess 649.

The first connecting portion 642 is located in the z2 direction from the first band-shaped portion 641. The shape and size of the first connecting portion 642 are not limited. In the illustrated example, the first connecting portion 642 has a rectangular shape that is elongated in the x direction. As shown in FIGS. 17, 20, and 21, the first connecting portion 642 is connected to the first metal part 35. The first path part 64 is hence connected to the supporting substrate 3. In the illustrated example, the first connecting portion 642 is bonded to the first metal part 35 via the conductive bonding material 69. Alternatively, the first connecting portion 642 may be bonded to the first metal part 35 by ultrasonic bonding, laser bonding, welding, or other methods. In the illustrated example, the first connecting portion 642 overhangs the first metal part 35 in the y1 direction.

The first coupling portion 643 connects the first band-shaped portion 641 and the first connecting portion 642 at their ends in the y1 direction. In the illustrated example, the first coupling portion 643 extends in the z direction and has a rectangular shape that is elongated in the x direction.

The second path part 65 is located between the third bonding parts 61 and the fifth bonding part 63. In the illustrated example, the second path part 65 has a bend connected to the fifth bonding part 63. In plan view, the second path part 65 overlaps with the first conductive part 32A and the second metal part 36. The second path part 65 generally extends in the x direction.

The second path part 65 includes a second band-shaped portion 651, a second connecting portion 652, and a second coupling portion 653. The second band-shaped portion 651 is located in the z1 direction from the fifth bonding part 63 and is substantially parallel to the first obverse surface 301A. The second band-shaped portion 651 generally extends in the x direction. In the illustrated example, the second band-shaped portion 651 has a recess 659. The recess 659 is a portion of the second band-shaped portion 651 that is recessed in the y2 direction. In FIG. 5, the second metal part 36 is visible through the recess 659.

The second connecting portion 652 is located in the z2 direction from the second band-shaped portion 651. The shape and size of the second connecting portion 652 are not limited. In the illustrated example, the second connecting portion 652 has a rectangular shape that is elongated in the x direction. As shown in FIG. 20, the second connecting portion 652 is connected to the second metal part 36. The second path part 65 is hence connected to the supporting substrate 3. In the illustrated example, the second connecting portion 652 is bonded to the second metal part 36 via the conductive bonding material 69. Alternatively, the second connecting portion 652 may be bonded to the second metal part 36 by ultrasonic bonding, laser bonding, welding, or other methods. In the illustrated example, the second connecting portion 652 overhangs the second metal part 36 in the y2 direction.

The second coupling portion 653 connects the second band-shaped portion 651 and the second connecting portion 652 at their ends in the y2 direction. In the illustrated example, the second coupling portion 653 extends in the z direction and has a rectangular shape that is elongated in the X direction.

When the first path part 64 according to variations and other embodiments is described below, the configurations of the first path part 64 may also be applied to the second path part 65 because the first path part 64 and the second path part 65 are symmetrical with respect to, for example, the centerline extending in the x direction.

The third path parts 66 are connected to the third bonding parts 61. The third path parts 66 extend in the x direction and spaced apart from each other in the y direction. The number of the third path parts 66 to be provided is not limited. In the illustrated example, five third path parts 66 are provided. Each third path part 66 is located either between the relevant third bonding parts 61 in the y direction or outward of the third bonding parts 61 in the y direction. The third path parts 66 are located in the z1 direction from the third bonding parts 61. Each third path part 66 has a bend connected to a third bonding part 61.

The two outermost third path parts 66 in the y direction are formed with recesses 669. Each recess 669 is recessed from the inner side toward the outer side in the y direction. In the illustrated example, each relevant third path part 66 is formed with two recesses 669. In FIG. 5, the first conductive part 32A and the second conductive part 32B are visible through the recesses 669.

The fourth path part 67 is connected to the ends of the third path parts 66 in the x1 direction. The fourth path part 67 extends in the y direction. The fourth path part 67 is connected to the end of the first band-shaped portion 641 of the first path part 64 located in the x2 direction and also to the end of the second band-shaped portion 651 of the second path part 65 located in the x2 direction. In the illustrated example, the fourth path part 67 is connected to the first path part 64 at its end in the y1 direction and to the second path part 65 at its end in the y2 direction.

The sealing resin 8 covers the first semiconductor elements 10A, the second semiconductor elements 10B, the supporting substrate 3 (except for the reverse surface 302), a portion of each of the first to fourth terminals 41, 42, 43, and 44, a portion of each control terminal 45, the control terminal support 48, the first conductive member 5, the second conductive member 6, and the wires 71 to 74. The sealing resin 8 may be made of a black epoxy resin, for example. The sealing resin 8 may be formed by molding, for example. In one example, the sealing resin 8 has an x-direction dimension of about 35 to 60 mm, a y-direction dimension of about 35 to 50 mm, and a z-direction dimension of about 4 to 15 mm. These dimensions are measured at the largest portions in the respective directions. The sealing resin 8 has a resin obverse surface 81, a resin reverse surface 82, and resin side surfaces 831 to 834.

As shown in FIGS. 10, 12, and 18 in particular, the resin obverse surface 81 and the resin reverse surface 82 are spaced apart in the z direction. The resin obverse surface 81 faces in the z1 direction, and the reverse surface 82 faces in the z2 direction. The control terminals 45 (the first control terminals 46A to 46E and the second control terminals 47A to 47D) protrude from the resin obverse surface 81. As shown in FIG. 11, the resin reverse surface 82 has the shape of a frame surrounding the reverse surface 302 (the lower surface of the reverse-surface metal layer 33) of the supporting substrate 3 in plan view. The reverse surface 302 of the supporting substrate 3 is exposed from the resin reverse surface 82 and is flush with the resin reverse surface 82, for example. The resin side surfaces 831 to 834 are connected to both the resin obverse surface 81 and the resin reverse surface 82 and are located between the resin obverse surface 81 and the resin reverse surface 82 in the z direction. As shown in FIG. 4 in particular, the resin side surfaces 831 and 832 are spaced apart in the x direction. The resin side surface 831 faces in the x2 direction, and the resin side surface 832 faces in the x1 direction. The two third terminals 43 protrude from the resin side surface 831, whereas the first terminal 41, the second terminal 42, and the fourth terminal 44 protrude from the resin side surface 832. As shown in FIG. 4 in particular, the resin side surfaces 833 and 834 are spaced apart in the y direction. The resin side surface 833 faces in the y2 direction, and the resin side surface 834 faces in the y1 direction.

As shown in FIG. 4, the resin side surface 832 is formed with a plurality of recesses 832a. Each recess 832a is recessed in the x direction in plan view. The recesses 832a include one formed between the first terminal 41 and the fourth terminal 44, and one formed between the second terminal 42 and the fourth terminal 44. The recesses 832a are provided to increase the creepage distance along the resin side surface 832 between the first terminal 41 and the fourth terminal 44 and also between the second terminal 42 and the fourth terminal 44.

As shown in FIGS. 12 and 13 in particular, the sealing resin 8 includes a plurality of first projections 851, a plurality of second projections 852, and a resin cavity 86.

The first projections 851 protrude from the resin obverse surface 81 in the z direction. The first projections 851 are located near the four corners of the sealing resin 8 in plan view. Each first projection 851 has a first-projection end surface 851a at its end (the end in the z1 direction). The first-projection end surfaces 851a of the first projections 851 are parallel (or substantially parallel) to the resin obverse surface 81 and are contained in the same plane (x-y plane). Each first projection 851 has the shape of a truncated hollow cone with a bottom, for example. The first projections 851 serve as spacers when the semiconductor device A1 is mounted on, for example, a control circuit board of a device that operates on the power generated by the semiconductor device A1. Each first projection 851 has a recess 851b and an inner wall 851c forming the recess 851b. Each first projection 851 is columnar, which preferably is a cylindrical column. The recess 851b has a cylindrical shape, preferably with the inner wall 851c defining one perfect circle in plan view.

The semiconductor device A1 may be mechanically fastened to the control circuit board or the like by screwing, for example. In such a case, each first projection 851 may have an internal thread on the inner wall 851c of the recess 851b. For example, an insert nut may be inserted into the recess 851b of each first projection 851.

As shown in FIG. 13 in particular, the second projections 852 protrude from the resin obverse surface 81 in the z direction. The second projections 852 overlap with the control terminals 45 in plan view. The metal pin 452 of each control terminal 45 protrudes from a relevant second projection 852. Each second projection 852 has the shape of a truncated cone. Each second projection 852 covers the holder 451 and a portion of the metal pin 452 of a relevant control terminal 45.

Next, the operation and effect of the present embodiment will be described.

The second conductive member 6 is connected to the supporting substrate 3. The second conductive member 6 electrically connects the second semiconductor elements 10B and the first terminal 41. The first terminal 41 is located on the side of the first conductive part 32A in the x1 direction, which is opposite to the second semiconductor elements 10B. The second conductive member 6 is expected to generate heat when a large current flows through it. Since the second conductive member 6 is connected to the supporting substrate 3, heat generated in the second conductive member 6 is transferred to the supporting substrate 3 and is then dissipated from the semiconductor device A1. Therefore, the semiconductor device A1 is capable of handling larger electric currents and improving heat dissipation.

The second conductive member 6 includes the first path part 64. At least about half of the main circuit current of the second semiconductor elements 10B flows through the first Connecting the first path part 64 to the path part 64. supporting substrate 3 thus ensures that heat generated in response to the current flow is efficiently transferred to the supporting substrate 3.

The second conductive member 6 includes the second path part 65, and the second path part 65 is connected to the supporting substrate 3 (the second metal part 36). Thus, both the first path part 64 and the second path part 65 contribute to transfer of heat to the supporting substrate 3. This further improves the heat dissipating efficiency of the semiconductor device A1.

In addition, the first path part 64 and the second path part 65, which are respectively connected to the first terminal 41 and the second terminal 42, are connected to the supporting substrate 3. This ensures that heat generated by external components and devices connected to the semiconductor device A1 is efficiently transferred to the supporting substrate 3. This ensures that heat from external sources does not affect the second semiconductor elements 10B, for example.

The first connecting portion 642 of the first path part 64 is connected to the first metal part 35 of the supporting substrate 3. The first metal part 35 is insulated from the first conductive part 32A and the second conductive part 32B. This ensures that an unexpected current path is not formed when the first path part 64 is electrically bonded to the first metal part 35. In addition, a joint formed by electrical bonding is typically highly heat conductive and thus is preferable for improving heat dissipating efficiency.

The first connecting portion 642 positionally coincides with the recess 649 in the x direction. The current conduction area is locally restricted in a portion having the recess 649, so that heat tends to be generated in that portion. The first connecting portion 642 is located near such a portion. Thus, connecting the first connecting portion 642 to the supporting substrate 3 is effective for improving heat dissipation efficiency. Additionally, during the manufacture of the semiconductor device A1, the recess 649 may serve to provide a space for placing a jig used to hold an appropriate portion and to facilitate the flow of resin material for forming the sealing resin 8.

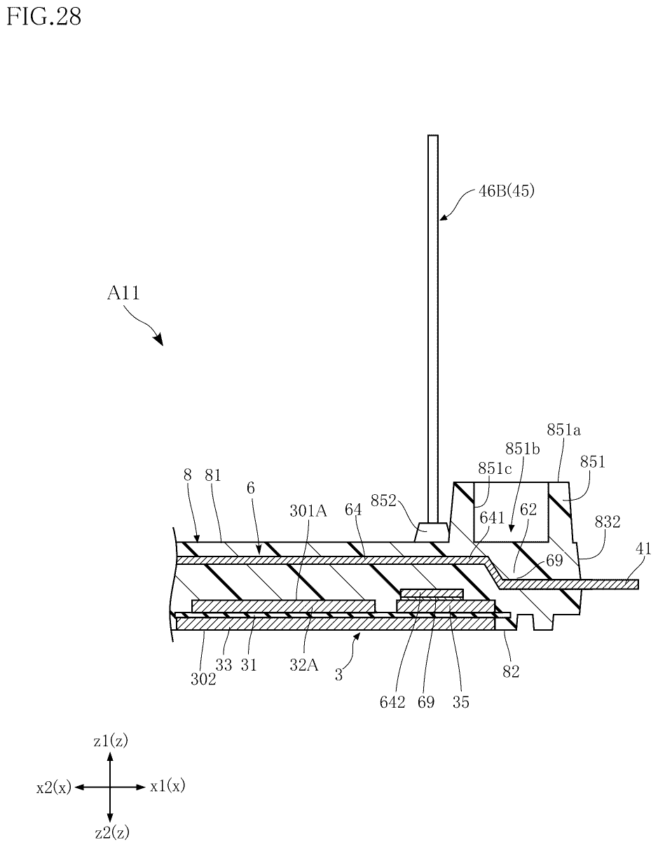

FIGS. 28 to 36 show other embodiments. In these figures, elements that are identical or similar to those described in the embodiment described above are indicated by the same reference numerals. In addition, the configuration of each part of any embodiment or variation can be combined unless a technical contradiction arises.

### First Variation of First Embodiment:

FIG. 28 shows a first variation of the semiconductor device A1. In a semiconductor device All of the present variation, the first terminal 41 is integrally formed with the second conductive member 6. That is, the first terminal 41 and the second conductive member 6 are fabricated, for example, from a single metal plate by applying processes, such as cutting or bending.

The present variation enables the semiconductor device to handle larger electric currents and improve heat dissipation. As can be understood from the present variation, the second conductive member 6 and the first terminal 41, which are electrically connected to each other, may be either separate components electrically connected via a bonded part or integral parts of a single unit. Also, the second conductive member 6 and the second terminal 42 may be integrally formed.

### Second Variation of First Embodiment:

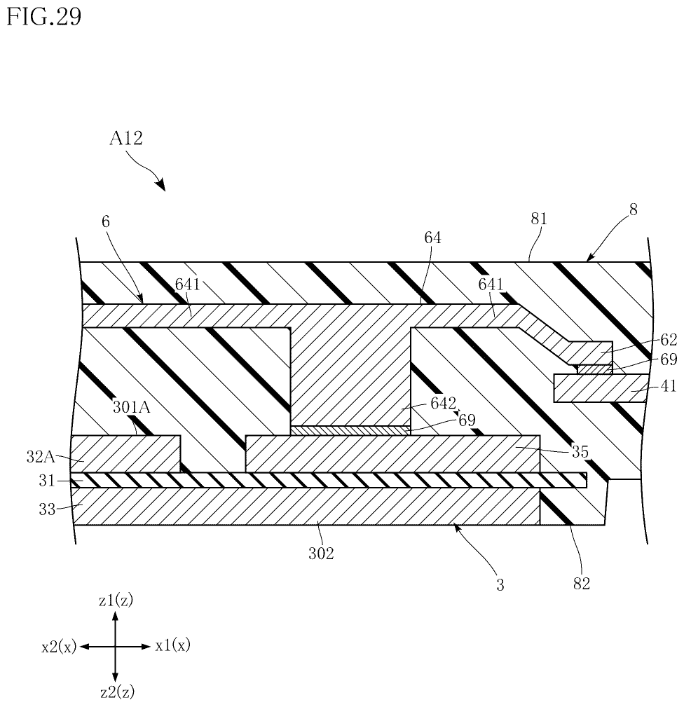

FIG. 29 shows a second variation of the semiconductor device A1. In a semiconductor device A12 of the present variation, the configuration of the first path part 64 differs from that of the example described above. The first path part 64 of the present variation includes a first band-shaped portion 641 and a first connecting portion 642.

The first connecting portion 642 of the present variation is a protrusion extending from the first band-shaped portion 641 in the z2 direction. The first connecting portion 642 is bonded at its end surface in the z2 direction to the first metal part 35 via the conductive bonding material 69. In an alternative example, the first connecting portion 642 may be bonded by solid-state diffusion bonding, rather than via the conductive bonding material 69.

The present variation enables the semiconductor device to handle larger electric currents and improve heat dissipation. In addition, the first connecting portion 642 has a block shape extending from the first band-shaped portion 641 and thus is effective in improving dissipation of heat to the first metal part 35 (the supporting substrate 3).

### Third Variation of First Embodiment:

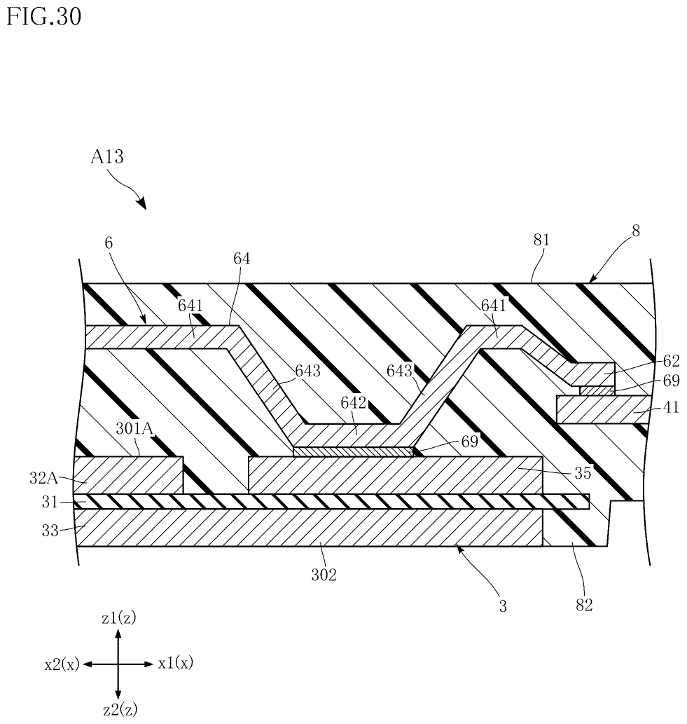

FIG. 30 shows a third variation of the semiconductor device A1. In a semiconductor device A13 of the present variation, the configuration of the first path part 64 differs from that of the examples described above. The first path part 64 of the present variation includes two first band-shaped portions 641, a first connecting portion 642, and two first coupling portions 643.

The two first band-shaped portions 641 are spaced apart from each other in the x direction. The first connecting portion 642 is located between the two first band-shaped portions 641 in the x direction. The first connecting portion 642 is located in the z2 direction from the two first band-shaped portions 641. The first connecting portion 642 is bonded to the first metal part 35 via the conductive bonding material 69, for example. Each of the two first coupling portions 643 connects one of the opposite ends of the first connecting portion 642 in the x direction and one of the two first band-shaped portions 641. The shape of the first coupling portions 643 is not limited. In the illustrated example, the first coupling portions 643 are inclined relative to the z direction. Specifically, the first coupling portions 643 are inclined to be away from each other in the x direction with approach toward the z1 direction.

The present variation enables the semiconductor device to handle larger electric currents and improve heat dissipation. The first connecting portion 642 passes the main circuit current. When heat is generated in the first connecting portion 642, the heat can be quickly transferred to the first metal part 35.

### Second Embodiment

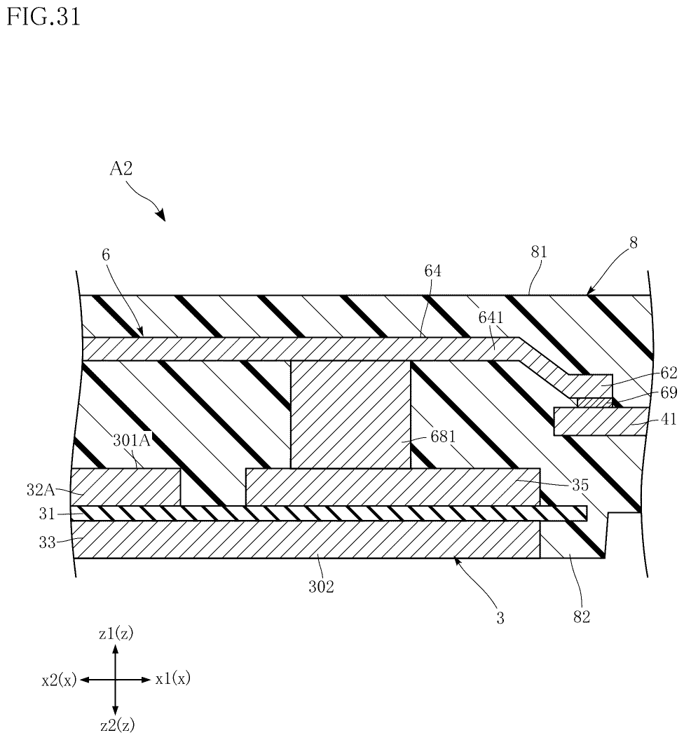

FIG. 31 shows a semiconductor device according to a second embodiment of the present disclosure. Different from the semiconductor device of the embodiment described above, the semiconductor device A2 of the present embodiment includes an intermediate metal body 681.

The intermediate metal body 681 is made of metal and may have a block shape, for example. The intermediate metal body 681 is bonded to the first band-shaped portion 641 and the first metal part 35. The method of bonding the intermediate metal body 681 to the first band-shaped portion 641 and the first metal part 35 is not limited. In the illustrated example, the bonding is achieved by ultrasonic bonding.

The present embodiment enables the semiconductor device handle larger electric and currents improve heat to dissipation. As can be understood from the present embodiment, the second conductive member 6 (the first path part 64) may be connected to the supporting substrate 3 via another component, such as the intermediate metal body 681.

### First Variation of Second Embodiment:

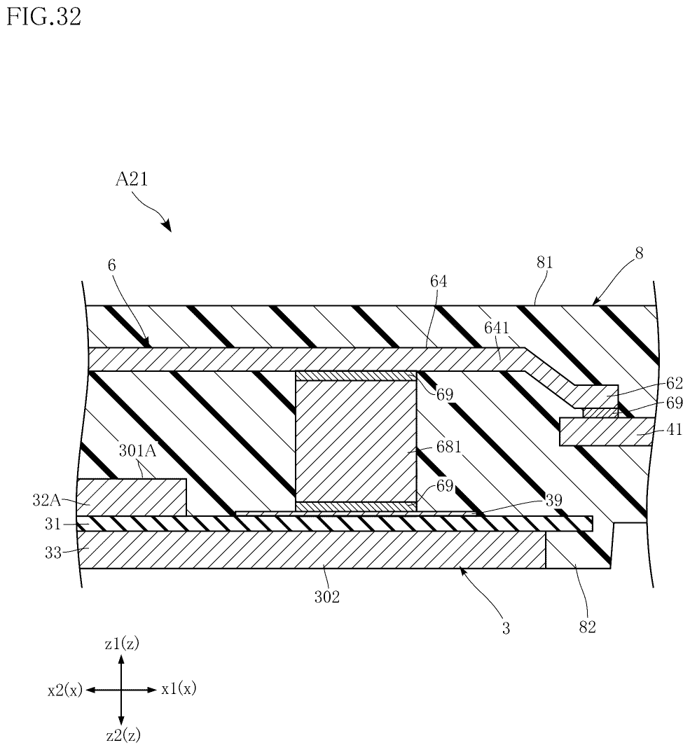

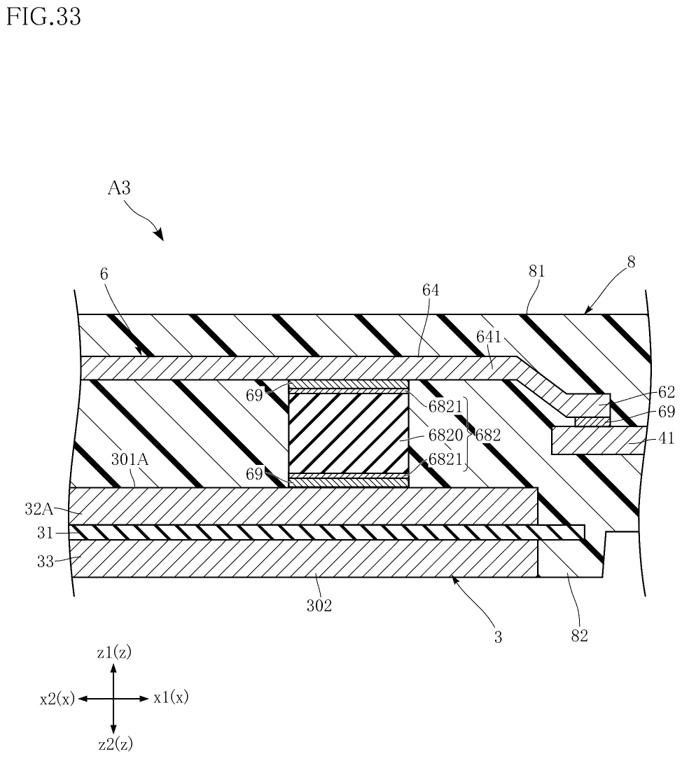

FIG. 32 shows a first variation of the semiconductor device A2. In the semiconductor device A21 of the present variation, the supporting substrate 3 does not include a first metal part 35.

In the present variation, the intermediate metal body 681 is connected to the first band-shaped portion 641 and the insulating layer 31. The intermediate metal body 681 and the first band-shaped portion 641 of the first path part 64 may be bonded via the conductive bonding material 69, for example. The insulating layer 31 may be formed with a metal layer 39 for bonding. The bonding metal layer 39 is a metal plating layer or the like, and may be thinner than the first conductive part 32A, for example. By bonding the intermediate metal body 681 and the bonding metal layer 39 via the conductive bonding material 69, for example, the intermediate metal body 681 is connected to the insulating layer 31 (the supporting substrate 3).

The present variation enables the semiconductor device to handle larger electric currents and improve heat dissipation. In addition, the intermediate metal body 681 connected to the insulating layer 31 facilitates the efficient transfer of heat generated in the second conductive member 6 toward the reverse surface 302 of the supporting substrate 3.

### Third Embodiment

FIG. 33 shows a semiconductor device according to a third embodiment of the present disclosure. Different from the semiconductor devices of the embodiments described above, the semiconductor device A3 of the present embodiment includes an intermediate insulator 682.

The intermediate insulator 682 is a component connecting the first path part 64 to the supporting substrate 3 (the first metal part 35). The intermediate insulator 682 insulates the first path part 64 and the first metal part 35 and may be made of an insulating material either entirely or partially.

In the illustrated example, the intermediate insulator 682 includes an insulating substrate 6820 and two bonding metal layers 6821. The intermediate insulator 682 may include a block made of silicon nitride (SiN), for example, as the insulating substrate 6820. Then, the bonding metal layers 6821 may be plating layers deposited on the opposite surfaces of the insulating substrate 6820 in the z direction.

In the present embodiment, the first conductive part 32A has such a size and shape that the first conductive part 32A overlaps with the intermediate insulator 682 in plan view. The intermediate insulator 682 is bonded to the first path part 64 (the first band-shaped portion 641) and the first conductive part 32A of the supporting substrate 3 via the conductive bonding material 69, for example.

The present embodiment enables the semiconductor device to handle larger electric currents and improve heat dissipation. In addition, the intermediate insulator 682 can connect the first path part 64 (the second conductive member 6) to the first conductive part 32A. That is, the first metal part 35 of the supporting substrate 3 is not essential, which helps to avoid a complex configuration of the supporting substrate 3. In addition, the first conductive part 32A is larger than the first metal part 35 and thus provides greater flexibility in selecting the location for connecting the first path part 64, or more precisely the location for connecting the intermediate metal body 681.

### First Variation of Third Embodiment:

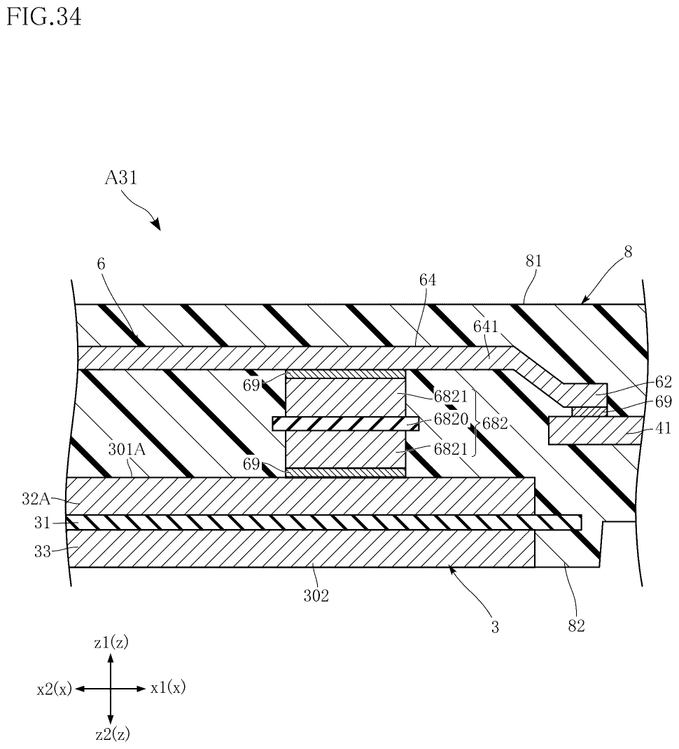

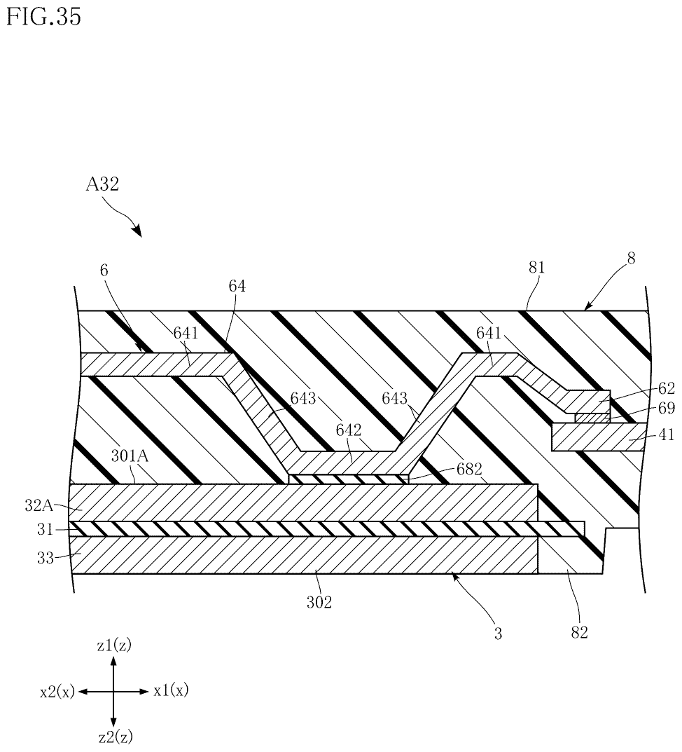

FIG. 34 shows a first variation of the semiconductor device A3. In a semiconductor device A31 of the present variation, the configuration of the intermediate insulator 682 differs from that of the example described above. The intermediate insulator 682 of the present variation is composed of a DBC substrate.

In this example, the insulating substrate 6820 is thinner than the insulating substrate 6820 of the semiconductor device A3. In addition, the bonding metal layers 6821 are thinner than the bonding metal layers 6821 of the semiconductor device A3.

The present variation enables the semiconductor device to handle electric currents and improve heat dissipation. As can be understood from the present variation, the specific configuration of the intermediate insulator 682 is not limited.

### Second Variation of Third Embodiment:

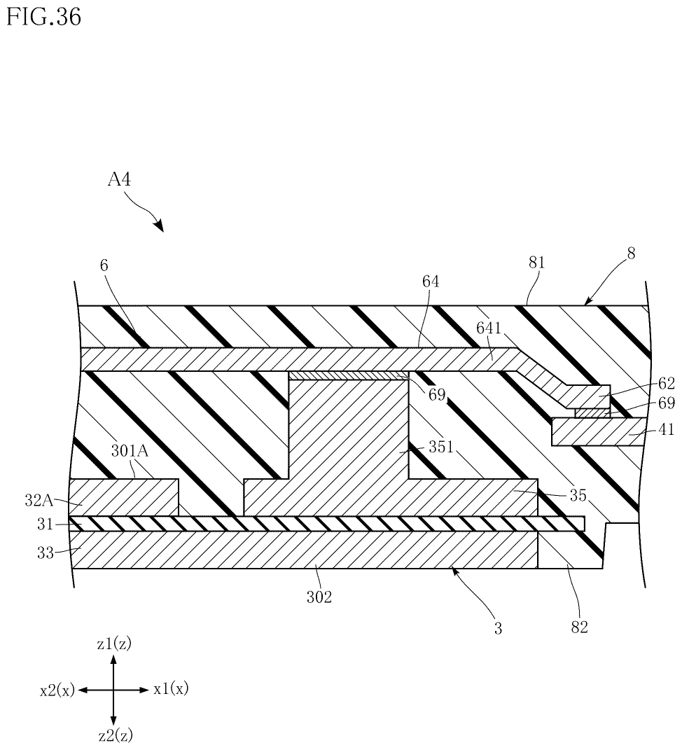

FIG. 35 shows a second variation of the semiconductor device A3. In a semiconductor device A32 of the present variation, the first path part 64 is similar in configuration to the first path part 64 in the semiconductor device A13 described above. The intermediate insulator 682 of the present variation may be made of a bonding material containing an insulating resin, for example. In the present variation, the first connecting portion 642 is bonded to the first conductive part 32A via the intermediate insulator 682.

The present variation enables the semiconductor device to handle larger electric currents and improve heat dissipation. In addition, when a bonding material containing resin is selected for the intermediate insulator 682, the intermediate insulator 682 will absorb thermal deformation that may occur in the supporting substrate 3 (the first conductive part 32A) and the second conductive member 6, thereby reducing the deformation difference between them.

### Fourth Embodiment

FIG. 36 shows a semiconductor device according to a fourth embodiment of the present disclosure. In a semiconductor device A4 of the present embodiment, the first metal part 35 is different in configuration from that of the embodiments described above.

The first metal part 35 of the present embodiment includes a protrusion 351. The protrusion 351 is a portion of the first metal part 35 that protrudes in the z1 direction. The protrusion 351 is bonded to the first path part 64 via the conductive bonding material 69 or by other bonding methods described above. The first path part 64 is hence connected to the supporting substrate 3.

The present embodiment enables the semiconductor device to handle larger electric currents and improve heat dissipation. As can be understood from the present embodiment, the configuration of the bond between the second conductive member 6 and the supporting substrate 3 is not limited.

The semiconductor device according to the present disclosure is not limited to the embodiments described above. Various modifications in design may be made freely in the specific structure of each part of the semiconductor device according to the present disclosure.

The present disclosure includes embodiments described in the following clauses.

### Clause 1.

A semiconductor device comprising:
a supporting substrate including a first conductive part that includes a first obverse surface facing a first side in a thickness direction and is located on a first side in a first direction orthogonal to the thickness direction, and a second conductive part that includes a second obverse surface facing the first side in the thickness direction and is located on a second side in the first direction;
a plurality of first semiconductor elements mounted on the first conductive part and each having a switching function;
a plurality of second semiconductor elements mounted on the second conductive part and each having a switching function;
a first terminal protruding to the first side in the first direction from the first conductive part;
a first conductive member electrically connecting the plurality of first semiconductor elements and the second conductive part;
a second conductive member electrically connecting the plurality of second semiconductor elements and the first terminal; and
a sealing the plurality of first resin covering semiconductor elements, the plurality of second semiconductor elements, the first conductive member, the second conductive member, a portion of the supporting substrate, and a portion of the first terminal,
wherein the second conductive member is connected to the supporting substrate.

### Clause 2.

The semiconductor device according to Clause 1, wherein the first conductive part includes a plurality of first bonding parts bonded to the plurality of first semiconductor elements, and a second bonding part bonded to the second conductive member,
the second conductive member includes a plurality of third bonding parts bonded to the plurality of second semiconductor elements, a fourth bonding part bonded to the first terminal, and a first path part interposed between the plurality of third bonding parts and the fourth bonding part, and
the first path part is connected to the supporting substrate.

### Clause 3.

The semiconductor device according to Clause 2, further comprising a second terminal protruding to the first side in the first direction from the first conductive part and located on a second side in a second direction orthogonal to the thickness direction and the first direction,
wherein the second conductive member includes a fifth bonding part bonded to the second terminal, and a second path part interposed between the plurality of third bonding parts and the fifth bonding part with respect to the first terminal, and
the second path part is connected to the supporting substrate.

### Clause 4.

The semiconductor device according to Clause 3, wherein the first conductive member extends in the second direction,
the second conductive member includes a plurality of third path parts individually connected to the plurality of third bonding parts and extending in the first direction, and a fourth path part connected to an end of each of the plurality of third path parts located on the first side in the first direction and extending in the second direction, and
the first path part extends from the fourth path part to the first side in the first direction.

### Clause 5.

The semiconductor device according to Clause 4, wherein the first path part is connected to an end of the fourth path part located on a first side in the second direction.

### Clause 6.

The semiconductor device according to Clause 4 or 5, wherein the supporting substrate further includes an insulating layer fixed to the first conductive part and the second conductive part and located on a second side in the thickness direction with respect to the first conductive part and the second conductive part.

### Clause 7.

The semiconductor device according to Clause 6, wherein the supporting substrate includes a first metal part spaced apart from the first conductive part and the second conductive part and made of metal, and
the first path part is connected to the first metal part.

### Clause 8.

The semiconductor device according to Clause 7, wherein the supporting substrate includes a second metal part spaced apart from the first conductive part, the second conductive part, and the first metal part and made of metal, and
the second path part is connected to the second metal part.

### Clause 9.

The semiconductor device according to Clause 7 or 8, wherein the first path part is bonded to the first metal part via a metal-containing bonding material.

### Clause 10.

The semiconductor device according to Clause 7 or 8, wherein the first path part is connected to the first metal part via an intermediate metal body.

### Clause 11.

The semiconductor device according to Clause 6, wherein the first path part is connected to the insulating layer.

### Clause 12.

The semiconductor device according to Clause 11, wherein the first path part is connected to the insulating layer via an intermediate metal body.

### Clause 13.

The semiconductor device according to Clause 6, wherein the first path part is connected to the first conductive part via an intermediate insulator.

### Clause 14.

The semiconductor device according to any one of Clauses 6 to 13, wherein the supporting substrate includes a metal layer located on the second side in the thickness direction with respect to the insulating layer.

### Clause 15.

The semiconductor device according to any one of Clauses 3 to 14, wherein the first path part includes a first band-shaped portion extending in the first direction, and a first connecting portion located on a second side in the thickness direction with respect to the first band-shaped portion, and
the first connecting portion is connected to the supporting substrate.

### Clause 16.

The semiconductor device according to Clause 15, wherein
the first path part includes a first coupling portion connecting an end of the first band-shaped portion located on a first side in the second direction and an end of the first connecting portion located on the first side in the second direction.

### Clause 17.

The semiconductor device according to Clause 15, wherein
the first path part includes two first band-shaped portions located on opposite sides of the first connecting portion in the first direction, and two first coupling portions connecting opposite ends of the first connecting portion in the first direction and the two first band-shaped portions.

### REFERENCE NUMERALS

A1, A11, A12, A13, A2, A21: Semiconductor device
A3, A31, A32, A4: Semiconductor device
3: Supporting substrate 5: First conductive member
6: Second conductive member 8: Sealing resin
10A: First semiconductor element
10B: Second semiconductor element
11: First obverse-surface electrode
12: Second obverse-surface electrode
13: Third obverse-surface electrode
15: Reverse-surface electrode
17: Thermistor 19: Conductive bonding material
31: Insulating layer 32: First metal layer
32A: First conductive part 32B: Second conductive part
35: First metal part 33: Reverse-surface metal layer
36: Second metal part 39: Bonding metal layer
41: First terminal 42: Second terminal
43: Third terminal 44: Fourth terminal
45: Control terminal
46A, 46B, 46C, 46D, 46E: First control terminal
47A, 47B, 47C, 47D: Second control terminal
48: Control terminal support 48A: First support part
48B: Second support part 49: Bonding material
51: Main part
52: First bonding part
59: Conductive bonding material 53: Second bonding part
61: Third bonding part
63: Fifth bonding part
62: Fourth bonding part
64: First path part
66: Third path part 65: Second path part
67: Fourth path part 69: Conductive bonding material
71, 72, 73, 74: Wire 81: Resin obverse surface
82: Resin reverse surface 86: Resin cavity
101: Element obverse surface 102: Element reverse surface
301A: First obverse surface 301B: Second obverse surface
302: Reverse surface 351: Protrusion
451: Holder 452: Metal pin
481: Insulating layer 459: Conductive bonding material
482: First metal layer 482A: First part
482B: Second part 482C: Third part
482D: Fourth part 482E: Fifth part
482F: Sixth part 483: Second metal layer
514: First opening 641: First band-shaped portion
642: First connecting portion 643: First coupling portion
649: Recess 651: Second band-shaped portion
652: Second connecting portion 653: second coupling portion
659, 669: Recess 681: Intermediate metal body
682: Intermediate insulator
831, 832, 833, 834: Resin side surface
832a: Recess 851: First projection
851a: First-projection end surface 851b: Recess
851c: Inner wall 852: Second projection
6820: Insulating substrate 6821: Bonding metal layer

1. A semiconductor device comprising:
a supporting substrate including a first conductive part that includes a first obverse surface facing a first side in a thickness direction and is located on a first side in a first direction orthogonal to the thickness direction, and a second conductive part that includes a second obverse surface facing the first side in the thickness direction and is located on a second side in the first direction;
a plurality of first semiconductor elements mounted on the first conductive part and each a switching function;
a plurality of second semiconductor elements mounted on the second conductive part and each having a switching function;
a first terminal protruding to the first side in the first direction from the first conductive part;
a first conductive member electrically connecting the plurality of first semiconductor elements and the second conductive part;
a second conductive member electrically connecting the plurality of second semiconductor elements and the first terminal; and
a sealing resin covering sealing the plurality of first semiconductor elements, the plurality of second semiconductor elements, the first conductive member, the second conductive member, a portion of the supporting substrate, and a portion of the first terminal,
wherein the second conductive member is connected to the supporting substrate.

2. The semiconductor device according to claim 1, wherein the first conductive part includes a plurality of first bonding parts bonded to the plurality of first semiconductor elements, and a second bonding part bonded to the second conductive member,
the second conductive member includes a plurality of third bonding parts bonded to the plurality of second semiconductor elements, a fourth bonding part bonded to the first terminal, and a first path part interposed between the plurality of third bonding parts and the fourth bonding part, and
the first path part is connected to the supporting substrate.

3. The semiconductor device according to claim 2, further comprising a second terminal protruding to the first side in the first direction from the first conductive part and located on a second side in a second direction orthogonal to the thickness direction and the first direction with respect to the first terminal,
wherein the second conductive member includes a fifth bonding part bonded to the second terminal, and a second path part interposed between the plurality of third bonding parts and the fifth bonding part, and
the second path part is connected to the supporting substrate.

4. The semiconductor device according to claim 3, wherein the first conductive member extends in the second direction,
the second conductive member includes a plurality of third path parts individually connected to the plurality of third bonding parts and extending in the first direction, and a fourth path part connected to an end of each of the plurality of third path parts located on the first side in the first direction and extending in the second direction, and
the first path part extends from the fourth path part to the first side in the first direction.

5. The semiconductor device according to claim 4, wherein the first path part is connected to an end of the fourth path part located on a first side in the second direction.

6. The semiconductor device according to claim 4, wherein the supporting substrate further includes an insulating layer fixed to the first conductive part and the second conductive part and located on a second side in the thickness direction with respect to the first conductive part and the second conductive part.

7. The semiconductor device according to claim 6, wherein the supporting substrate includes a first metal part spaced apart from the first conductive part and the second conductive part and made of metal, and
the first path part is connected to the first metal part.

8. The semiconductor device according to claim 7, wherein the supporting substrate includes a second metal part spaced apart from the first conductive part, the second conductive part, and the first metal part and made of metal, and
the second path part is connected to the second metal part.

9. The semiconductor device according to claim 7, wherein the first path part is bonded to the first metal part via a metal-containing bonding material.

10. The semiconductor device according to claim 7, wherein the first path part is connected to the first metal part via an intermediate metal body.

11. The semiconductor device according to claim 6, wherein the first path part is connected to the insulating layer.

12. The semiconductor device according to claim 11, wherein the first path part is connected to the insulating layer via an intermediate metal body.

13. The semiconductor device according to claim 6, wherein the first path part is connected to the first conductive part via an intermediate insulator.

14. The semiconductor device according to claim 6, wherein the supporting substrate includes a metal layer located on the second side in the thickness direction with respect to the insulating layer.

15. The semiconductor device according to claim 3, wherein the first path part includes a first band-shaped portion extending in the first direction, and a first connecting portion located on a second side in the thickness direction with respect to the first band-shaped portion, and
the first connecting portion is connected to the supporting substrate.

16. The semiconductor device according to claim 15, wherein
the first path part includes a first coupling portion connecting an end of the first band-shaped portion located on a first side in the second direction and an end of the first connecting portion located on the first side in the second direction.

17. The semiconductor device according to claim 15, wherein
the first path part includes two first band-shaped portions located on opposite sides of the first connecting portion in the first direction, and two first coupling portions connecting opposite ends of the first connecting portion in the first direction and the two first band-shaped portions.
